(19) United States
(12) Patent Application Publication
(10) Pub. No.: US 2026/0051284 A1
(43) Pub. Date: Feb. 19, 2026

(54) DISPLAY PANEL AND ELECTRONIC DEVICE INCLUDING THE SAME

(71) Applicant: Samsung Display Co., Ltd., Yongin-Si (KR)

(72) Inventors: DOYEONG PARK, Yongin-si (KR); DONG HEE SHIN, Yongin-si (KR)

(21) Appl. No.: 19/251,467

(22) Filed: Jun. 26, 2025

(30) Foreign Application Priority Data
Aug. 16, 2024 (KR) 10-2024-0109791

(51) Int. Cl. G09G 3/32

(52) U.S. Cl. CPC G09G 3/32; G09G 2300/0426; G09G 2310/08

(57) ABSTRACT

A display panel includes a plurality of pixels, a stage including a plurality of transistors, a plurality of clock lines electrically connected to the stage, and a plurality of connecting lines that connect the plurality of clock lines to the plurality of transistors. The plurality of transistors include a plurality of first group transistors connected to (2N−1)th pixels arranged in the first direction among the plurality of pixels, and a plurality of second group transistors connected to 2N-th pixels arranged in the first direction among the plurality of pixels. The plurality of first group transistors and the plurality of second group transistors are spaced apart from each other with respect to a virtual reference line that line extends in a second direction crossing the first direction.

### CROSS-REFERENCE TO RELATED APPLICATIONS

This application claims priority under 35 U.S.C. § 119 to Korean Patent Application No. 10-2024-0109791 filed on Aug. 16, 2024, in the Korean Intellectual Property Office, the disclosures of which are incorporated by reference herein in their entireties.

### BACKGROUND

Embodiments of the present disclosure described herein relate to a display panel having a reduced width of a non-display area and an electronic device including the same.

Multimedia electronic devices, such as a television, a mobile phone, a tablet computer, a computer, a car navigation unit, a game machine, and the like, include a display panel for displaying an image. Due to market demand for a narrow bezel, researches have been conducted to reduce an area (a non-display area or a bezel area) of a display panel that does not display an image.

### SUMMARY

Embodiments of the present disclosure provide a display panel having a reduced width of a non-display area and an electronic device including the same.

According to an embodiment, a display panel includes a plurality of pixels arranged in a first direction, a stage including a plurality of transistors connected to the plurality of pixels and outputting a plurality of scan signals to the plurality of pixels, a plurality of clock lines electrically connected to the stage, and a plurality of connecting lines connecting the plurality of clock lines to the plurality of transistors. The plurality of transistors include a plurality of first group transistors connected with (2N−1)th pixels arranged in the first direction, wherein N is an integer, among the plurality of pixels, and a plurality of second group transistors connected with 2N-th pixels arranged in the first direction among the plurality of pixels. The plurality of first group transistors and the plurality of second group transistors are spaced apart from each other with respect to a virtual reference line between the first group transistors and the second group transistors, and the virtual reference line extends in a second direction crossing the first direction.

The plurality of connecting lines may include a plurality of first group connecting lines connected to the plurality of first group transistors and a plurality of second group connecting lines connected to the plurality of second group transistors. The plurality of first group connecting lines and the plurality of second group connecting lines may be spaced apart from each other with respect to the virtual reference line between the plurality of first group connecting lines and the second group connecting lines.

A first area in which the plurality of clock lines are disposed, a second area in which the stage is disposed, and a third area between the first area and the second area may be defined in the display panel, and the plurality of connecting lines may have a bent shape in the third area.

The third area may include a first boundary that is adjacent to the first area and that extends in the first direction, and a second boundary that is adjacent to the second area and that extends in the first direction. Positions of at least one of the first group connecting lines at the first boundary and the second boundary may be aligned with each other in the second direction, and positions of at least one other of the first group connecting lines at the first boundary and the second boundary may be not aligned with each other in the second direction.

A first distance between the plurality of first group connecting lines and the plurality of second group connecting lines at the first boundary may be less than a second distance between the plurality of first group connecting lines and the plurality of second group connecting lines at the second boundary.

The plurality of clock lines, the stage, and the plurality of pixels may be sequentially arranged in the second direction. Each of the plurality of clock lines may extend in the first direction, and each of the plurality of clock lines may be spaced apart from one another in the second direction.

The plurality of clock lines may include a plurality of first group clock lines electrically connected to the plurality of first group connecting lines and a plurality of second group clock lines electrically connected to the plurality of second group connecting lines. The plurality of first group clock lines and the plurality of second group clock lines may alternate with one another in the second direction.

The plurality of clock lines may include a first clock line, a second clock line, a third clock line, a fourth clock line, a fifth clock line, and a sixth clock line. The plurality of transistors may include a first transistor, a second transistor, a third transistor, a fourth transistor, a fifth transistor, and a sixth transistor, each of the first to the sixth transistors may be electrically connected to the first to sixth clock lines, respectively. The plurality of pixels may include a first pixel, a second pixel, a third pixel, a fourth pixel, a fifth pixel, and a sixth pixel, and each of the first to sixth pixels may be sequentially arranged in the first direction and connected to the first to sixth transistors in a one-to-one manner.

The first transistor and the second transistor may be spaced apart from each other with respect to the virtual reference line, the third transistor and the fourth transistor may be spaced apart from each other with respect to the virtual reference line, and the fifth transistor and the sixth transistor may be spaced apart from each other with respect to the virtual reference line.

The first transistor may be disposed closer to the plurality of clock lines than the fifth transistor, and the third transistor may be disposed between the first transistor and the fifth transistor. The second transistor may be disposed closer to the plurality of clock lines than the sixth transistor, and the fourth transistor may be disposed between the second transistor and the sixth transistor.

A gap between the first transistor and the second transistor may be less than a gap between the fifth transistor and the sixth transistor.

The display panel may further include a voltage line disposed between the stage and the plurality of pixels, and a plurality of intermediate connecting lines including a first intermediate connecting line, a second intermediate connecting line, a third intermediate connecting line, a fourth intermediate connecting line, a fifth intermediate connecting line, and a sixth intermediate. Each of the plurality of intermediate connecting lines may be connected to the first to sixth transistors in a one-to-one manner, and the first to sixth intermediate connecting lines may be sequentially arranged in the first direction in an area where the voltage line is disposed.

The fifth transistor may be disposed closer to the plurality of clock lines than the first transistor, and the third transistor may be disposed between the first transistor and the fifth transistor. The sixth transistor may be disposed closer to the plurality of clock lines than the second transistor, and the fourth transistor may be disposed between the second transistor and the sixth transistor.

A gap between the first transistor and the second transistor may be greater than a gap between the fifth transistor and the sixth transistor.

In a first mode in which the display panel operates at a first frequency, a plurality of clock signals transferred to the plurality of clock lines may have different phases from one another, and in a second mode in which the display panel operates at a second frequency higher than the first frequency, at least two clock signals among the plurality of clock signals may have the same phase.

According to an embodiment, an electronic device includes a display panel in which a display area and a non-display area adjacent to the display area are defined. The display panel includes a plurality of pixels disposed in the display area and a stage that is disposed in the non-display area and that outputs a plurality of scan signals to the plurality of pixels. The plurality of pixels include a first pixel, a second pixel, a third pixel, a fourth pixel, a fifth pixel, and a sixth pixel, which are sequentially arranged in a first direction. The stage includes a first transistor, a second transistor, a third transistor, a fourth transistor, a fifth transistor, and a sixth transistor, which are connected to the first to sixth pixels in a one-to-one manner and output the plurality of scan signals. The first transistor and the second transistor face each other in the first direction, the third transistor and the fourth transistor face each other in the first direction, and the fifth transistor and the sixth transistor face each other in the first direction. The third transistor is disposed between the first transistor and the fifth transistor, and the fourth transistor is disposed between the second transistor and the sixth transistor.

The display panel may further include a plurality of clock lines that are disposed in the non-display area and that provide a plurality of clock signals to the stage, and a plurality of connecting lines that are disposed in the non-display area and include a first connecting line, a second connecting line, a third connecting line, a fourth connecting line, a fifth connecting line, and a sixth connecting line. The first to sixth connecting lines may be connected to the first to sixth transistors in a one-to-one manner and may transfer the plurality of clock signals. The first connecting line, the third connecting line, and the fifth connecting line may be spaced apart from the second connecting line, the fourth connecting line, and the sixth connecting line with respect to a virtual reference line that extends in a second direction.

A first area in which the plurality of clock lines are disposed, a second area in which the stage is disposed, and a third area between the first area and the second area may be defined in the display panel. The third area may include a first boundary that is adjacent to the first area and that extends in the first direction, and a second boundary that is adjacent to the second area and that extends in the first direction. The first to sixth connecting lines may have a bent shape in the third area.

A first distance between the first connecting line and the second connecting line at the first boundary may be less than a second distance between the first connecting line and the second connecting line at the second boundary.

A first distance between the fifth connecting line and the sixth connecting line at the first boundary may be less than a second distance between the fifth connecting line and the sixth connecting line at the second boundary.

### BRIEF DESCRIPTION OF THE DRAWINGS

The above and other features of the present disclosure will become apparent by describing embodiments of the present disclosure in detail with reference to the accompanying drawings.

FIG. 1 is a perspective view of an electronic device according to an embodiment of the present disclosure.

FIG. 2 is a plan view of the electronic device according to an embodiment of the present disclosure.

FIG. 3 is a block diagram of the electronic device according to an embodiment of the present disclosure.

FIG. 4 is an equivalent circuit diagram of a pixel according to an embodiment of the present disclosure.

FIG. 5 is a block diagram illustrating some components of the display panel according to an embodiment of the present disclosure.

FIG. 6A is a view illustrating a scan drive circuit according to an embodiment of the present disclosure.

FIG. 6B is illustrating an equivalent circuit diagram of one stage of a scan drive circuit according to an embodiment of the present disclosure.

FIG. 7 is a timing diagram for explaining an operation of the stage in a first mode according to an embodiment of the present disclosure.

FIG. 8 is a timing diagram illustrating a plurality of clock signals to explain an operation of the stage in a second mode according to an embodiment of the present disclosure.

FIG. 9 is a view illustrating activation states of a first-type scan signal and a second-type scan signal and a change in luminance according to an embodiment of the present disclosure.

FIG. 10 is a view illustrating activation states of a first-type scan signal and a second-type scan signal and a change in luminance according to an embodiment of the present disclosure.

FIG. 11 is a plan view of a portion of a display panel according to an embodiment of the present disclosure.

FIG. 12 is an enlarged plan view illustrating area AA′ of FIG. 11 according to an embodiment of the present disclosure.

FIG. 13 is an enlarged plan view illustrating a portion of the display panel according to an embodiment of the present disclosure.

FIG. 14 is a sectional view of the display panel taken along a line I-I′ of FIG. 13 according to an embodiment of the present disclosure.

FIG. 15 is a sectional view of the display panel taken along a line II-II′ of FIG. 13 according to an embodiment of the present disclosure.

FIG. 16 is a plan view of a portion of a display panel according to an embodiment of the present disclosure.

FIG. 17 is a plan view of a portion of a display panel according to an embodiment of the present disclosure.

### DETAILED DESCRIPTION

In this specification, it will be understood that when a component (or, an area, a layer, a part, etc.) is referred to as being “on”, “connected to” or “coupled to” another component, the component may be directly on, connected to, or coupled to the other component, or indirectly on, connected or coupled to the other component with an intervening component being presented therebetween.

Identical reference numerals refer to identical components. Additionally, in the drawings, the thicknesses, proportions, and dimensions of components are exaggerated for effective description of the technical features of the present disclosure. As used herein, the term “and/or” includes all of one or more combinations defined by related components.

It will be understood that, although terms, such as first, second, and the like, may be used to describe various components, the components should not be limited by the terms. The terms may be used only for distinguishing one component from other components. For example, without departing from the scope of the present disclosure, a first component may be referred to as a second component. Similarly, the second component may also be referred to as the first component. The terms of a singular form may include plural forms unless clearly indicated otherwise.

In addition, terms, such as “below”, “under”, “above”, and “over,” are used to describe a spatial relationship between components illustrated in the drawings. The above terms are relative concepts and are described based on directions illustrated in the drawing.

It should be understood that terms, such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

The terms, such as “part” and “unit,” mean a software component or a hardware component that performs a specific function. The hardware component may include, for example, a field-programmable gate array (FPGA) or an application-specific integrated circuit (ASIC). The software component may refer to executable code and/or data used by executable code in an addressable storage medium. Thus, software components may be, for example, object-oriented software components, class components, and working components, and may include processes, functions, properties, procedures, subroutines, program code segments, drivers, firmware, micro-codes, circuits, data, databases, data structures, tables, arrays or variables.

Unless defined otherwise, all terms used herein, including technical or scientific terms, have the same meanings as those generally understood by those skilled in the art to which the present disclosure pertains. It will be understood that terms, such as those defined in commonly used dictionaries, should be interpreted as having a meaning that is consistent with their meaning in the context of the relevant art and will not be interpreted in an idealized or overly formal sense unless expressly defined as having such in this specification.

Hereinafter, embodiments of the present disclosure will be described with reference to the accompanying drawings.

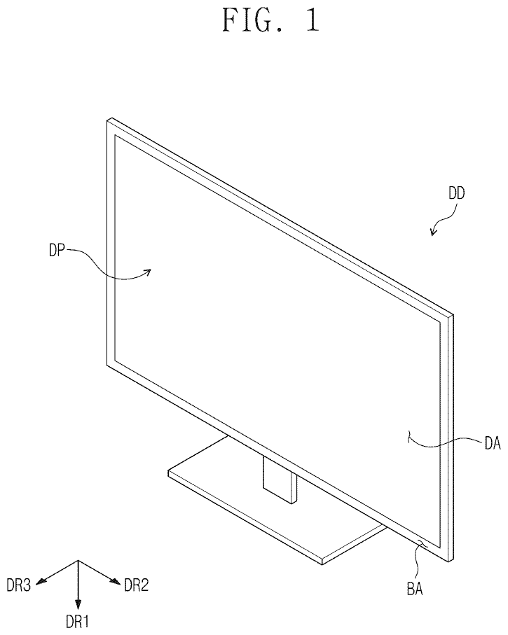

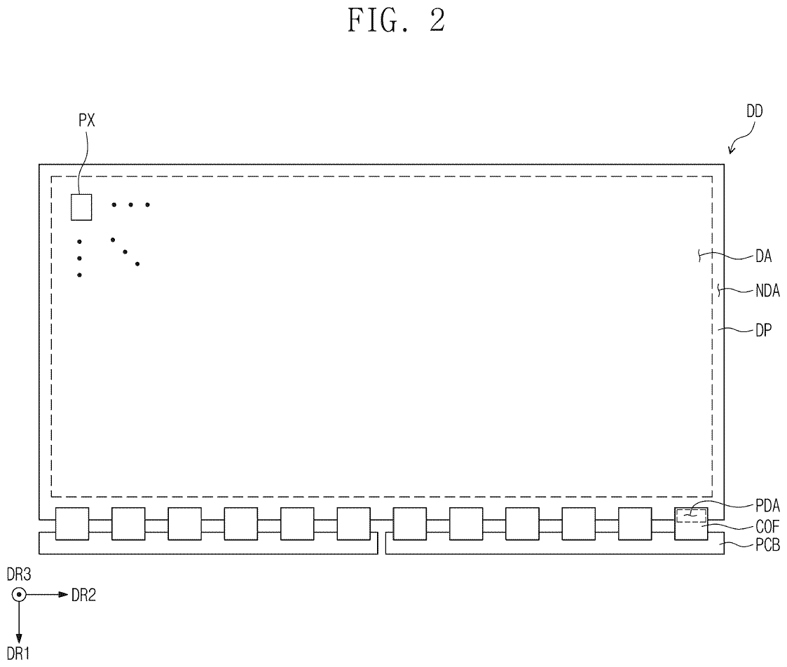

FIG. 1 is a perspective view of an electronic device DD according to an embodiment of the present disclosure. FIG. 2 is a plan view of the electronic device DD according to an embodiment of the present disclosure.

Referring to FIGS. 1 and 2, the electronic device DD may be a device which is activated based on an electrical signal. The electronic device DD may be used not only for large electronic devices, such as a television, a monitor, and a billboard, but also for small and medium-sized electronic devices, such as a personal computer, a notebook computer, a personal digital assistant, a car navigation unit, a game machine, a portable electronic device, and a camera. However, these devices are merely illustrative, and the electronic device DD may be employed for other electronic devices without departing from the spirit and scope of the present disclosure. For convenience of explanation, FIG. 1 illustrates an example where the electronic device DD is implemented as a monitor.

The electronic device DD may include a display panel DP, a connecting film COF, and a circuit board PCB.

The display panel DP may be a component that substantially displays an image. The display panel DP may be an emissive display panel. For example, the display panel DP may be an organic light emitting display panel, an inorganic light emitting display panel, an organic-inorganic light emitting display panel, a quantum-dot display panel, a micro-LED display panel, or a nano-LED display panel, but the type of the display panel DP is not particularly limited thereto. The display panel DP may have a small or medium size in a range from a few inches to a dozen inches or less. The display panel DP may have a large size having several tens of inches or more.

The display panel DP may have a display area DA and a non-display area NDA surrounding at least a portion of the display area DA. The display panel DP may display an image through the display area DA. For example, the display panel DP may include a plurality of pixels PX, and the pixels PX may be disposed in the display area DA. The display area DA may include a plane defined by a first direction DR1 and a second direction DR2. The display area DA may display an image in a third direction DR3 that crosses the first direction DR1 and the second direction DR2. The non-display area NDA may surround the periphery of the display area DA.

A bezel area BA of the electronic device DD may cover at least a portion of the non-display area NDA of the display panel DP. The bezel area BA may cover the entire non-display area NDA or may cover a portion of the non-display area NDA. As the area of the non-display area NDA decreases, the area of the bezel area BA may also be reduced accordingly.

The connecting film COF may be provided in plural. A drive circuit for driving the display panel DP, for example, a data drive circuit, may be mounted on each of the connecting films COF. The plurality of connecting films COF may be coupled to the non-display area NDA of the display panel DP. For example, the connecting films COF may be attached to one side of the display panel DP. In an embodiment of the present disclosure, the connecting films COF may be coupled to pad areas PDA of the display panel DP. The pad areas PDA may be defined in the non-display area NDA of the display panel DP. The connecting films COF and the display panel DP may be coupled together by an anisotropic conductive film (ACF). However, the present disclosure is not limited thereto.

The display device DD may include one circuit board PCB or a plurality of circuit boards PCB. Each of the circuit boards PCB may be electrically connected to the display panel DP through corresponding connecting films among the plurality of connecting films COF. A chip for controlling an operation of the display panel DP, for example, a timing controller, may be mounted on the circuit board PCB.

Although FIG. 2 illustrates twelve connecting films COF, the present disclosure is not limited thereto. Although two circuit boards PCB are illustrated in FIG. 2, the present disclosure is not limited thereto. For example, the number of connecting films COF and the number of circuit boards PCB may vary depending on the resolution of the display panel DP, the size of the display panel DP, and the specifications of the data drive circuit.

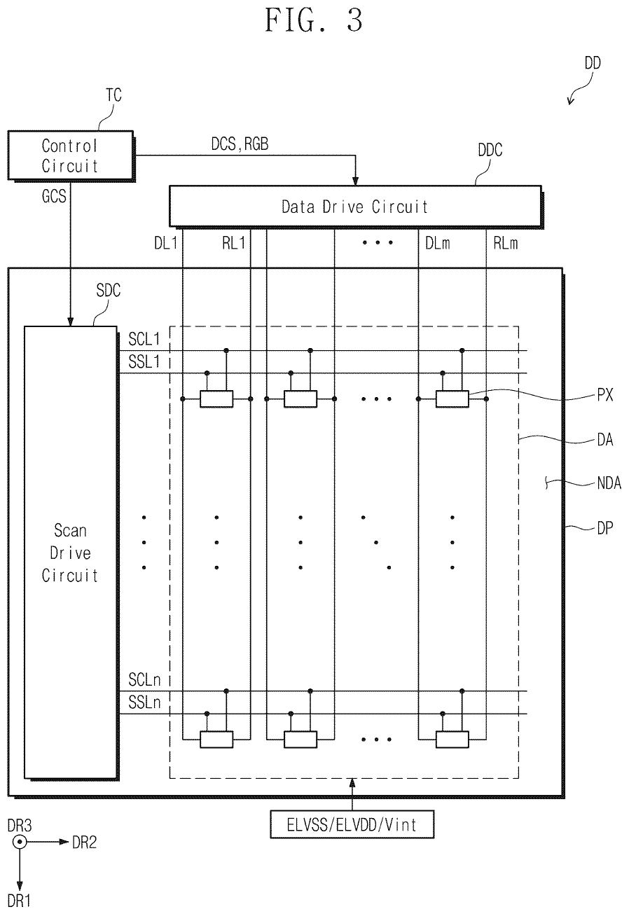

FIG. 3 is a block diagram of the electronic device DD according to an embodiment of the present disclosure.

Referring to FIGS. 2 and 3, the electronic device DD may include the display panel DP, a scan drive circuit SDC, a data drive circuit DDC, and a control circuit TC.

The display panel DP includes the display area DA which displays an image and the non-display area NDA disposed outside the display area DA. The plurality of pixels PX may be disposed in the display area DA. The scan drive circuit SDC for driving the pixels PX may be disposed in the non-display area NDA.

The scan drive circuit SDC may be directly formed on a base layer through a photolithography process. For example, through a process of forming pixel circuits of the pixels PX, the scan drive circuit SDC may be simultaneously formed with the pixel circuits.

The control circuit TC controls operations of the scan drive circuit SDC and the data drive circuit DDC. The control circuit TC generates image data RGB by converting the data format of input image signals according to the specification of an interface with the data drive circuit DDC. The control circuit TC outputs the image data RGB and various control signals DCS and GCS.

The scan drive circuit SDC receives the first control signal GCS from the control circuit TC. The first control signal GCS may include a vertical start signal that starts an operation of the scan drive circuit SDC and a clock signal that determines when to output signals. The scan drive circuit SDC may output a plurality of scan signals to a plurality of scan lines SCL1 to SCLn and SSL1 to SSLn (here, “n” may be an integer of 2 or more). The scan drive circuit SDC may be referred to as a gate drive circuit.

The data drive circuit DDC receives the second control signal DCS and the image data RGB from the control circuit TC. The data drive circuit DDC converts the image data RGB into data signals and outputs the data signals to a plurality of data lines DL1 to DLm (here, “m” may be an integer of 2 or more). The data signals are analog voltages corresponding to gray level values of the image data RGB. The data drive circuit DDC may be provided in the form of a driver chip and may be mounted on the connecting films COF, the circuit boards PCB, or the non-display area NDA of the display panel DP.

The display panel DP may include the plurality of scan lines SCL1 to SCLn and SSL1 to SSLn, the plurality of data lines DL1 to DLm, a plurality of readout lines RL1 to RLm, and the plurality of pixels PX.

The scan lines SCL1 to SCLn and SSL1 to SSLn may be arranged in the first direction DR1, and each of the scan lines SCL1 to SCLn and SSL1 to SSLn may extend in the second direction DR2 crossing the first direction DR1. The scan lines SCL1 to SCLn and SSL1 to SSLn may include the first-type scan lines SCL1 to SCLn and the second-type scan lines SSL1 to SSLn. The first-type scan lines SCL1 to SCLn may be referred to as first scan lines, write scan lines, or first gate lines, and the second-type scan lines SSL1 to SSLn may be referred to as second scan lines, initialization scan lines, sensing scan lines, or second gate lines.

The data lines DL1 to DLm may be arranged in the second direction DR2, and each of the data lines DL1 to DLm may extend in the first direction DR1. The readout lines RL1 to RLm may be arranged in the second direction DR2, and each of the readout lines RL1 to RLm may extend in the first direction DR1. The data lines DL1 to DLm and the readout lines RL1 to RLm may be insulated from the scan lines SCL1 to SCLn and SSL1 to SSLn and may cross the scan lines SCL1 to SCLn and SSL1 to SSLn.

Each of the pixels PX may be connected to corresponding scan lines among the scan lines SCL1 to SCLn and SSL1 to SSLn, a corresponding data line among the data lines DL1 to DLm, and a corresponding readout line among the readout lines RL1 to RLm. For example, the pixels PX arranged in the first row may be connected to the first first-type scan line SCL1 and the first second-type scan line SSL1, and the pixels PX arranged in the n-th row may be connected to the n-th first-type scan line SCLn and the n-th second-type scan line SSLn. The pixels PX arranged in the first column may be connected to the first data line DL1 and the first readout line RL1, and the pixels PX arranged in the m-th column may be connected to the m-th data line DLm and the m-th readout line RLm. However, this is only an example, and the connection relationship between the pixels PX and the scan lines SCL1 to SCLn and SSL1 to SSLn, the data lines DL1 to DLm, and the readout lines RL1 to RLm is not limited thereto.

The display panel DP receives a first power supply voltage ELVDD and a second power supply voltage ELVSS. The first power supply voltage ELVDD may be provided to the pixels PX. The display panel DP may receive an initialization voltage Vint. The initialization voltage Vint may be provided to the pixels PX.

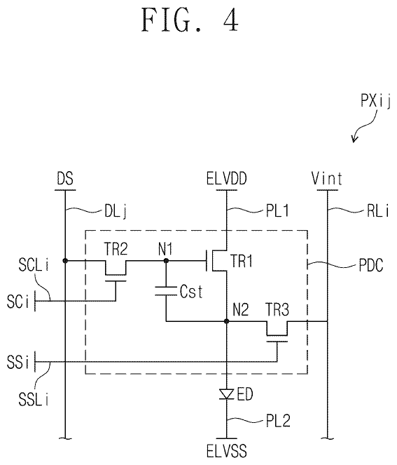

FIG. 4 is an equivalent circuit diagram of a pixel PXij according to an embodiment of the present disclosure.

In FIG. 4, an equivalent circuit diagram of one pixel PXij among the plurality of pixels PX (refer to FIG. 3) is illustrated as an example. Since the plurality of pixels PX have the same circuit structure, description of the circuit structure of the pixel PXij may be applied to the remaining pixels PX, and detailed description of the remaining pixels PX will be omitted. Here, “i” may be an integer greater than or equal to 1 and less than or equal to n, and “j” may be an integer greater than or equal to 1 and less than or equal to m.

Referring to FIG. 4, the pixel PXij includes a light emitting element ED and a pixel drive circuit PDC. The pixel PXij may be connected to the i-th scan lines SCLi and SSLi among the scan lines SCL1 to SCLn and SSL1 to SSLn, the j-th data line DLj among the data lines DL1 to DLm, and the j-th readout line RLj among the readout lines RL1 to RLm. The i-th scan lines SCLi and SSLi may include the i-th first-type scan line SCLi and the i-th second-type scan line SSLi.

The pixel drive circuit PDC may include a first transistor TR1, a second transistor TR2, a third transistor TR3, and a capacitor Cst. The configuration of the pixel drive circuit PDC according to the present disclosure is not limited to the embodiment illustrated in FIG. 4. The pixel drive circuit PDC illustrated in FIG. 4 is only an example, and the configuration of the pixel drive circuit PDC may be modified. For example, the pixel drive circuit PDC may further include at least one transistor and at least one capacitor.

In an embodiment of the present disclosure, each of the first transistor TR1, the second transistor TR2, and the third transistor TR3 is described as an N-type thin film transistor. However, the present disclosure is not limited thereto. For example, at least one of the first transistor TR1, the second transistor TR2, and the third transistor TR3 may be a P-type thin film transistor.

In addition, each of the first transistor TR1, the second transistor TR2, and the third transistor TR3 may be a transistor having an oxide semiconductor layer. However, the present disclosure is not particularly limited thereto. For example, at least one of the first transistor TR1, the second transistor TR2, and the third transistor TR3 may be a transistor having a low-temperature polycrystalline silicon (LTPS) semiconductor layer.

The first transistor TR1 may be electrically connected between a first power line PL1 and the light emitting element ED. The first transistor TR1 may include a gate electrode connected to a first node N1, a first electrode electrically connected to the first power line PL1, and a second electrode connected to the light emitting element ED. The light emitting element ED and the first transistor TR1 may be electrically connected with each other at a second node N2. The first power supply voltage ELVDD may be provided to the pixel PXij through the first power line PL1.

The first transistor TR1 may control the amount of a driving current flowing to the light emitting element ED in response to the voltage of the first node N1. For example, the first transistor TR1 may be turned on when the voltage between the first node N1 and the second node N2 (that is, the gate-source voltage) is higher than the threshold voltage of the first transistor TR1.

The second transistor TR2 may be electrically connected between the j-th data line DLj and the first node N1. The second transistor TR2 may include a gate electrode connected to the i-th first-type scan line SCLi, a first electrode connected to the j-th data line DLj, and a second electrode connected to the first node N1.

The second transistor TR2 may transfer a data voltage DS received from the j-th data line DLj to the first node N1 in response to the i-th first-type scan signal SCi provided through the i-th first-type scan line SCLi. For example, the second transistor TR2 may be turned on when the i-th first-type scan signal SCi is at a logic high level.

The third transistor TR3 may be electrically connected between the second node N2 and the j-th readout line RLj. The third transistor TR3 may include a gate electrode connected to the i-th second-type scan line SSLi, a first electrode connected to the j-th readout line RLj, and a second electrode connected to the second node N2. The third transistor TR3 may connect the second node N2 to the j-th readout line RLj in response to the i-th second-type scan signal SSi provided through the i-th second-type scan line SSLi. For example, the third transistor TR3 may be turned on when the i-th second-type scan signal SSi is at a logic high level.

According to an embodiment of the present disclosure, during an image display operation, the third transistor TR3 may transfer the initialization voltage Vint to the second node N2 in response to the i-th second-type scan signal SSi. That is, when the third transistor TR3 is turned on, the second electrode of the first transistor TR1 may be reset to the initialization voltage Vint.

During a sensing operation, the third transistor TR3 may transfer a sensing current corresponding to the voltage of the second node N2 to the j-th readout line RLj in response to the i-th second-type scan signal SSi. The control circuit TC (refer to FIG. 3) may receive the sensing current, may determine the threshold voltage or mobility of the first transistor TR1, and may generate compensated image data RGB.

The capacitor Cst may be connected between the first node N1 and the second node N2. When the data voltage DS is supplied, the initialization voltage Vint may be supplied to the second node N2. In this case, the difference voltage between the data voltage DS and the initialization voltage Vint may be stored in the capacitor Cst. The voltage stored in the capacitor Cst may determine whether to turn on or turn off the first transistor TR1.

The light emitting element ED may be connected between the second node N2 and a second power line PL2. The second power supply voltage ELVSS may be applied to the second power line PL2. The light emitting element ED may include a first electrode (e.g., an anode), a second electrode (e.g., a cathode), and an emissive layer between the first electrode and the second electrode. For example, the first electrode may be connected to the second node N2, and the second electrode may be connected to the second power line PL2. The light emitting element ED may generate light having a certain luminance in response to the amount of the driving current provided from the first transistor TR1.

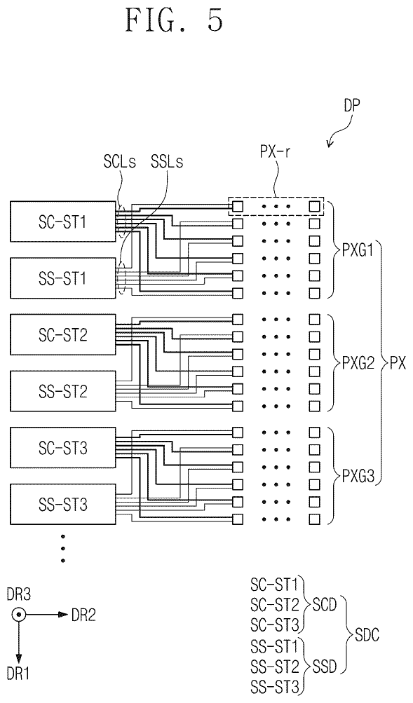

FIG. 5 is a block diagram illustrating some components of the display panel DP according to an embodiment of the present disclosure.

Referring to FIG. 5, a portion of the scan drive circuit SDC and pixels are illustrated. The scan drive circuit SDC may include a first-type scan drive circuit SCD and a second-type scan drive circuit SSD. The first-type scan drive circuit SCD may include a plurality of first-type stages SC-ST1, SC-ST2, and SC-ST3, and the second-type scan drive circuit SSD may include a plurality of second-type stages SS-ST1, SS-ST2, and SS-ST3.

According to an embodiment of the present disclosure, the first-type stages SC-ST1, SC-ST2, and SC-ST3 may be arranged in the first direction DR1, and the second-type stages SS-ST1, SS-ST2, and SS-ST3 may be arranged in the first direction DR1. The first-type stages SC-ST1, SC-ST2, and SC-ST3 and the second-type stages SS-ST1, SS-ST2, and SS-ST3 may alternate with one another in the first direction DR1.

According to an embodiment of the present disclosure, each of the first-type stages SC-ST1, SC-ST2, and SC-ST3 may be electrically connected to a plurality of first-type scan lines SCLs. In addition, each of the second-type stages SS-ST1, SS-ST2, and SS-ST3 may be electrically connected to a plurality of second-type scan lines SSLs. For example, a first first-type stage SC-ST1 may be connected to two or more first-type scan lines SCLs and may output two or more first-type scan signals, and a first second-type stage SS-ST1 may be connected to two or more second-type scan lines SSLs and may output two or more second-type scan signals.

Although FIG. 5 illustrates an example that the first first-type stage SC-ST1 is electrically connected to six first-type scan lines SCLs and the first second-type stage SS-ST1 is electrically connected to six second-type scan lines SSLs, the present disclosure is not particularly limited thereto. For example, any numbers of the first-type scan lines SCLs more than two may be connected to the first first-type stage SC-ST1, and any numbers of the second-type scan lines SSL more than twos may be connected to the first second-type stage SS-ST1.

According to an embodiment of the present disclosure, the plurality of pixels PX may be arranged in the first direction DR1 and the second direction DR2. Among the plurality of pixels PX, a row of pixels PX-r (hereinafter, referred to as the pixel row) arranged in the second direction DR2 may be connected to one first-type stage, e.g., the first first-type stage SC-ST1, and one second-type stage, e.g., the first second-type stage SS-ST1. The pixels PX arranged consecutively in a plurality of pixel rows may be referred to as a first pixel group PXG1, and the pixels PX in the first pixel group PXG1 may be connected to one first-type stage, for example, the first first-type stage SC-ST1, and one second-type stage, for example, the first second-type stage SS-ST1.

The first pixel groups PXG1 including six pixel rows PX-r may be connected to the first first-type stage SC-ST1 and the first second-type stage SS-ST1. The second pixel groups PXG2 including six pixel rows PX-r may be connected to the second first-type stage SC-ST2 and the second second-type stage SS-ST2. The third pixel groups PXG3 including six pixel rows PX-r may be connected to the third first-type stage SC-ST3 and the third second-type stage SS-ST3.

According to an embodiment of the present disclosure, one stage of the scan drive circuit SDC, for example, the first first-type stage SC-ST1, may control an operation of a pixel group which includes two or more pixel rows PX-r, for example, the first pixel group PXG1. That is, the total number of stages may be less than the number of the pixel rows PX-r. Accordingly, the numbers of transistors, capacitors, and lines (e.g., clock lines) disposed in the non-display area NDA (refer to FIG. 3) may be reduced. Thus, the width of the non-display area NDA (refer to FIG. 3) of the display panel DP (refer to FIG. 2) may be reduced accordingly.

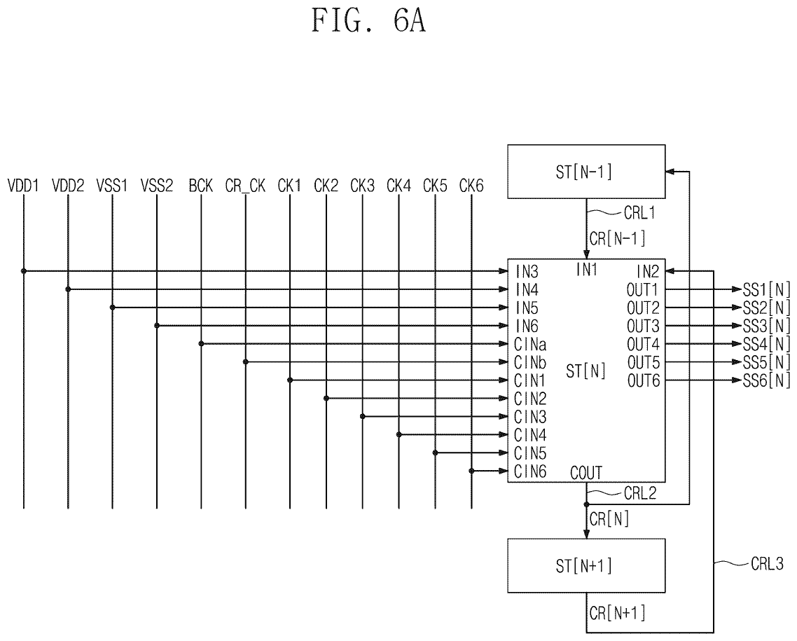

FIG. 6A is a view illustrating the scan drive circuit SDC according to an embodiment of the present disclosure. FIG. 6B is an equivalent circuit diagram illustrating one stage ST[N] of the scan drive circuit SDC according to an embodiment of the present disclosure.

In FIG. 6A, three stages ST[N−1], ST[N], and ST[N+1] are illustrated as an example. Here, N may be an integer of 2 or more. The three stages ST[N−1], ST[N], and ST[N+1] may be the first-type stages SC-ST1, SC-ST2, and SC-ST3 (refer to FIG. 5) or the second-type stages SS-ST1, SS-ST2, and SS-ST3 (refer to FIG. 5).

In FIG. 6B, the equivalent circuit diagram of the stage ST[N] of the scan drive circuit SDC is illustrated as an example. The remaining stages ST[N−1] and ST[N+1] also include substantially the same configuration, and therefore repetitive description will be omitted. The configuration of the stage ST[N] according to the present disclosure is not limited to the embodiment illustrated in FIG. 6B. The stage ST[N] illustrated in FIG. 6B is only an example, and the circuit configuration of the stage ST[N] may be modified.

The stages ST[N−1], ST[N], and ST[N+1] illustrated in FIG. 6A may be sequentially referred to as a first stage ST[N−1], a second stage ST[N], and a third stage ST[N+1]. In an embodiment, the second stage ST[N] may be referred to as a reference stage or a stage, the first stage ST[N−1] may be referred to as a first peripheral stage, and the third stage ST[N+1] may be referred to as a second peripheral stage. Hereinafter, the second stage ST[N] may be referred to as the stage.

The stage ST[N] may include first to sixth input terminals IN1, IN2, IN3, IN4, IN5, and IN6, first to sixth clock terminals CIN1, CIN2, CIN3, CIN4, CIN5, and CIN6, s first control terminal CINa, a second control terminal CINb, first to sixth output terminals OUT1, OUT2, OUT3, OUT4, OUT5, and OUT6, and a carry output terminal COUT.

The first input terminal IN1 of the stage ST[N] may receive a carry signal CR[N−1] output from the previous stage, for example, the first stage ST[N−1]. When the stage ST[N] is the first stage, the first input terminal IN1 may receive a start signal output from a dummy stage which is arranged prior to the first stage.

The carry signal CR[N−1] may be referred to as a previous carry signal or a first carry signal. Hereinafter, the carry signal CR[N−1] is referred to as the first carry signal CR[N−1]. The first stage ST[N−1] and the stage ST[N] may be electrically connected through a first carry line CRL1, and the first carry line CRL1 may be referred to as a first peripheral carry line. The first carry signal CR[N−1] generated in the first stage ST[N−1] may be transferred to the stage ST[N] through the first carry line CRL1.

The second input terminal IN2 of the stage ST[N] may receive a carry signal CR[N+1] output from the next stage, for example, the third stage ST[N+1]. When the stage ST[N] is the last stage, the second input terminal IN2 may receive a carry signal output from a dummy stage which is arranged after the last stage.

The carry signal CR[N+1] may be referred to as a next carry signal or a third carry signal. Hereinafter, the carry signal CR[N+1] is referred to as the third carry signal CR[N+1]. The third stage ST[N+1] and the stage ST[N] may be electrically connected through a third carry line CRL3, and the third carry line CRL3 may be referred to as a second peripheral carry line. The third carry signal CR[N+1] generated in the third stage ST[N+1] may be transferred to the stage ST[N] through the third carry line CRL3.

The third input terminal IN3 of the stage ST[N] may receive a first high voltage VDD1, and the fourth input terminal IN4 may receive a second high voltage VDD2. The voltage level of the second high voltage VDD2 may be greater than the voltage level of the first high voltage VDD1, but the voltage level of the second high voltage VDD2 or the first high voltage VDD1 is not particularly limited thereto. For example, the first high voltage VDD1 may be 15 V, and the second high voltage VDD2 may be 25 V.

The fifth input terminal IN5 of the stage ST[N] may receive a first low voltage VSS1, and the sixth input terminal IN6 may receive a second low voltage VSS2. The voltage level of the first low voltage VSS1 and the voltage level of the second low voltage VSS2 may be equal to or different from each other.

The stage ST[N] may receive a boost clock signal BCK through the first control terminal CINa and may receive a carry clock signal CR_CK through the second control terminal CINb. The stage ST[N] may receive first to sixth clock signals CK1, CK2, CK3, CK4, CK5, and CK6 through the first to sixth clock terminals CIN1, CIN2, CIN3, CIN4, CIN5, and CIN6, respectively. In an embodiment of the present disclosure, each of the first to sixth clock terminals CIN1, CIN2, CIN3, CIN4, CIN5, and CIN6 in each of the first stage ST[N−1] and the third stage ST[N+1] may receive a clock signal having a phase inverted from that of each of the first to sixth clock signals CK1, CK2, CK3, CK4, CK5, and CK6.

The carry output terminal COUT of the stage ST[N] may output a carry signal CR[N]. The carry signal CR[N] may be transferred to the first stage ST[N−1] and the third stage ST[N+1]. The carry signal CR[N] may be referred to as a second carry signal. The first stage ST[N−1], the stage ST[N], and the third stage ST[N+1] may be electrically connected through a second carry line CRL2. The second carry signal CR[N] generated in the stage ST[N] may be transferred to the first stage ST[N−1] and the third stage ST[N+1] through the second carry line CRL2.

The first to sixth output terminals OUT1, OUT2, OUT3, OUT4, OUT5, and OUT6 of the stage ST[N] may output first to sixth scan signals SS1[N], SS2[N], SS3[N], SS4[N], SS5[N], and SS6[N], respectively. The first to sixth scan signals SS1[N], SS2[N], SS3[N], SS4[N], SS5[N], and SS6[N] may be provided to, for example, six rows of pixels in one pixel group, e.g., PXG1, PXG2, or PXG3, respectively.

For example, the first to sixth scan signals SS1[N], SS2[N], SS3[N], SS4[N], SS5[N], and SS6[N] may be first scan signals (or, referred to as first-type scan signals) provided through the first-type scan lines SCLs (refer to FIG. 5), respectively. For example, the first to sixth scan signals SS1[N], SS2[N], SS3[N], SS4[N], SS5[N], and SS6[N] may be second scan signals (or, referred to as second-type scan signals) provided through the second-type scan lines SSLs (refer to FIG. 5), respectively.

Referring to FIG. 6B, the stage ST[N] may include a first node Q-C, a second node QB, a third node N-CQ, a fourth node N-B, and a plurality of split nodes Q-1 to Q-6. The first node Q-C may be referred to as a Q node, the plurality of split nodes Q-1 to Q-6 may be referred to as split Q nodes, and the second node QB may be referred to as a QB node.

The stage ST[N] may further include a first circuit S101, a second circuit S102, a third circuit S103, a fourth circuit S104, a fifth circuit S105, a sixth circuit S106, a seventh circuit S107, an eighth circuit S108, and a ninth circuit S109.

The first circuit S101 may control the voltage of the first node Q-C and may be referred to as a first node control circuit. The first circuit S101 may include first to fourth transistors T11, T12, T13, and T14.

The first transistor T11 and the second transistor T12 may be connected with each other in series. The first transistor T11 and the second transistor T12 may have a dual gate structure. The first transistor T11 and the second transistor T12 may be connected between the first input terminal IN1 and the first node Q-C. Both the gate electrode of the first transistor T11 and the gate electrode of the second transistor T12 may be connected to the first input terminal IN1. The fourth input terminal IN4 may be connected between the first transistor T11 and the second transistor T12. The first transistor T11 and the second transistor T12 may be turned on in response to the gate on-voltage (e.g., a logic high level) of the first carry signal CR[N−1], and the second transistor T12 may transfer the second high voltage VDD2 to the first node Q-C. The operation in which the second high voltage VDD2 is transferred to the first node Q-C may be referred to as a pre-charging operation or a first boosting operation. The third transistor T13 and the fourth transistor T14 may be connected with each other in series. The third transistor T13 and the fourth transistor T14 may have a dual gate structure. The third transistor T13 and the fourth transistor T14 may be connected between the first node Q-C and the sixth input terminal IN6. Both the gate electrode of the third transistor T13 and the gate electrode of the fourth transistor T14 may be connected to the second input terminal IN2. The third transistor T13 and the fourth transistor T14 may transfer the second low voltage VSS2 to the first node Q-C in response to the gate on-voltage (e.g., a logic high level) of the third carry signal CR[N+1].

The second circuit S102 may include a first transistor T21 and a second transistor T22. The first transistor T21 and the second transistor T22 may be connected with each other in series. The first transistor T21 and the second transistor T22 may be connected between the first node Q-C and the sixth input terminal IN6. Both the gate electrode of the first transistor T21 and the gate electrode of the second transistor T22 may be connected to the second node QB. The first transistor T21 and the second transistor T22 may transfer the second low voltage VSS2 to the first node Q-C in response to the voltage of the second node QB. Accordingly, the second circuit S102 may be referred to as a first node stabilization circuit.

The third circuit S103 may include a first transistor T31, a second transistor T32, a third transistor T33, a fourth transistor T34, and a fifth transistor T35.

The first transistor T31 may be connected between the second node QB and the third input terminal IN3. The second transistor T32 and the third transistor T33 may be connected with each other in series. The gate electrode of the second transistor T32 and the gate electrode of the third transistor T33 may be connected to the third input terminal IN3, and the second transistor T32 and the third transistor T33 may be connected between the third input terminal IN3 and the gate electrode of the first transistor T31.

The fourth transistor T34 may be connected between the gate electrode of the first transistor T31 and the fifth input terminal IN5, and the fifth transistor T35 may be connected between the second node QB and the sixth input terminal IN6. The gate electrode of the fourth transistor T34 and the gate electrode of the fifth transistor T35 may be connected to the first node Q-C.

The second transistor T32 and the third transistor T33 transfer the first high voltage VDD1 to the gate electrode of the first transistor T31 in response to the first high voltage VDD1. An operation of the fourth transistor T34 is controlled in response to the voltage of the first node Q-C. When the fourth transistor T34 is turned on, the first low voltage VSS1 may be transferred to the gate electrode of the first transistor T31.

The first transistor T31 may transfer the first high voltage VDD1 to the second node QB in response to the voltage of the gate electrode of the first transistor T31. An operation of the fifth transistor T35 is controlled in response to the voltage of the first node Q-C. When the fifth transistor T35 is turned on, the second low voltage VSS2 may be transferred to the second node QB.

The fourth circuit S104 may include a first transistor T41, a second transistor T42, and a capacitor C4.

The first transistor T41 may be connected between the first control terminal CINa and the fourth node N-B. The gate electrode of the first transistor T41 may be connected to the first node Q-C. An operation of the first transistor T41 is controlled in response to the voltage of the first node Q-C. When the first transistor T41 is turned on, a logic high level voltage, for example, a logic high level voltage of the boost clock signal BCK received through the first control terminal CINa, may be provided to the fourth node N-B.

The second transistor T42 may be connected between the fourth node N-B and the sixth input terminal IN6. The gate electrode of the second transistor T42 may be connected to the second node QB. An operation of the second transistor T42 is controlled in response to the voltage of the second node QB. When the second transistor T42 is turned on, the second low voltage VSS2 may be provided to the fourth node N-B.

The capacitor C4 is connected between the gate electrode of the first transistor T41 and the fourth node N-B. The capacitor C4 may increase (boost up) the voltage of the first node Q-C in response to an increase in the voltage of the fourth node N-B, and this operation may be referred to as a second boosting operation.

The fifth circuit S105 may include a first transistor T51 and a second transistor T52.

The first transistor T51 may be connected between the second control terminal CINb and the carry output terminal COUT. The gate electrode of the first transistor T51 may be connected to the first node Q-C. An operation of the first transistor T51 is controlled in response to the voltage of the first node Q-C. When the first transistor T51 is turned on, a logic high level voltage of the second carry signal CR[N] may be provided to the carry output terminal COUT.

The second transistor T52 may be connected between the carry output terminal COUT and the sixth input terminal IN6. The gate electrode of the second transistor T52 may be connected to the second node QB. An operation of the second transistor T52 is controlled in response to the voltage of the second node QB. When the second transistor T52 is turned on, the second low voltage VSS2 may be provided to the carry output terminal COUT.

The sixth circuit S106 may control the voltage of the third node N-CQ and may be referred to as a third node control circuit. The sixth circuit S106 may include a first transistor T61, a second transistor T62, and a third transistor T63.

The first transistor T61 and the second transistor T62 may be connected with each other in series. The first transistor T61 and the second transistor T62 may have a dual gate structure. The first transistor T61 and the second transistor T62 may be connected between the fourth input terminal IN4 and the third node N-CQ. Both the gate electrode of the first transistor T61 and the gate electrode of the second transistor T62 may be connected to the first input terminal IN1. The first transistor T61 and the second transistor T62 may transfer the second high voltage VDD2 to the third node N-CQ in response to the gate on-voltage (e.g., a logic high level) of the first carry signal CR[N−1].

The third transistor T63 may be connected between the third node N-CQ and the third input terminal IN3. The gate electrode of the third transistor T63 may be connected to the second input terminal IN2. The third transistor T63 may transfer the first high voltage VDD1 to the third node N-CQ in response to the gate on-voltage (e.g., a logic high level) of the third carry signal CR[N+1].

The seventh circuit S107 may include a transistor T71. The transistor T71 may be connected between the third input terminal IN3 and the third node N-CQ. The gate electrode of the transistor T71 may be connected to the fourth node N-B. The transistor T71 may provide the first high voltage VDD1 to the third node N-CQ in response to the voltage of the fourth node N-B.

The eighth circuit S108 may include a first transistor T81 and a second transistor T82.

The first transistor T81 and the second transistor T82 may be connected with each other in series. The first transistor T81 and the second transistor T82 may be connected between the third node N-CQ and the fifth input terminal IN5. Both the gate electrode of the first transistor T81 and the gate electrode of the second transistor T82 may be connected to the second node QB. The first transistor T81 and the second transistor T82 may transfer the first low voltage VSS1 to the third node N-CQ in response to the voltage of the second node QB. Accordingly, the sixth circuit S108 may be referred to as a third node stabilization circuit.

The ninth circuit S109 may include a plurality of output circuits S109s. In an embodiment of the present disclosure, the stage ST[N] may output six scan signals, and therefore the ninth circuit S109 may include six output circuits S109s. In FIG. 6B, the first output circuit and the last output circuit (e.g., the sixth output circuit) are illustrated as an example. However, it will be understood that each of the second to the fifth output circuit has the substantially same configuration of the first or the sixth output circuit.

Each of the output circuits S109s may include a first transistor T91, a second transistor S92, a third transistor T93, and a capacitor C9. Hereinafter, the first output circuit S109s will be described in detail. The remaining output circuits S109s may include substantially the same configuration, and therefore repetitive description will be omitted.

The first transistor T91 may be connected between the first clock terminal CIN1 and the first output terminal OUT1. The gate electrode of the first transistor T91 may be connected to the split node Q-1. The second transistor T92 may be connected between the first node Q-C and the split node Q-1. The gate electrode of the second transistor T92 may be connected to the third node N-CQ. In response to the voltage of the third node N-CQ, the second transistor T92 may connect the first node Q-C to the split node Q-1, or may disconnect the first node Q-C from the split node Q-1.

An operation of the first transistor T91 is controlled in response to the voltage of the split node Q-1. When the first transistor T91 is turned on, a logic high level voltage of the scan signal SS1[N] may be output to the first output terminal OUT1.

According to an embodiment of the present disclosure, the transistor T71 may be turned on when the fourth node N-B is boosted to have a logic high level voltage and may transfer the first high voltage VDD1 to the third node N-CQ. When the fourth node N-B is boosted, the voltage of the first node Q-C may be higher than the first high voltage VDD1 of the third node N-CQ. Accordingly, the second transistor T92 may be turned off. The second transistor T92 may separate the first node Q-C from the split node Q-1 in response to the voltage of the third node N-CQ.

While signals are output to the first to sixth output terminals OUT1, OUT2, OUT3, OUT4, OUT5, and OUT6, the first node Q-C and the split node Q-1 may be electrically isolated from each other, and the split nodes Q-1 to Q-6 may also be electrically isolated from one another. Accordingly, even if the voltage of the split node Q-1 is changed due to the coupling with the signal output to the first output terminal OUT1, an influence on other nodes may be eliminated. For example, the other nodes may be the first node Q-C and the remaining split nodes other than the split node Q-1 among the split nodes Q-1 to Q-6. Accordingly, horizontal line defects due to a luminance difference between lines may be eliminated.

According to an embodiment of the present disclosure, when the second low voltage VSS2 is transferred to the first node Q-C in response to the gate on-voltage of the third carry signal CR[N+1], the voltage of the first node Q-C may be lower than the voltage of the third node N-CQ. In this case, the second transistor T92 may be turned on. Accordingly, the first node Q-C and the split node Q-1 may be connected with each other, and the split node Q-1 may be discharged.

The third transistor T93 may be connected between the first output terminal OUT1 and the fifth input terminal IN5. As the gate electrode of the third transistor T93 is connected to the second node QB, an operation of the third transistor T93 may be controlled in response to the voltage of the second node QB. When the third transistor T93 is turned on, the first low voltage VSS1 may be provided to the first output terminal OUT1.

The capacitor C9 is connected between the split node Q-1 and the fourth node N-B. The capacitor C9 may increase (boost up) the voltage of the split node Q-1 in response to an increase in the voltage of the fourth node N-B. When the voltage of the split node Q-1 is increased, the scan signal SS1[N] having a high voltage may be output without distortion.

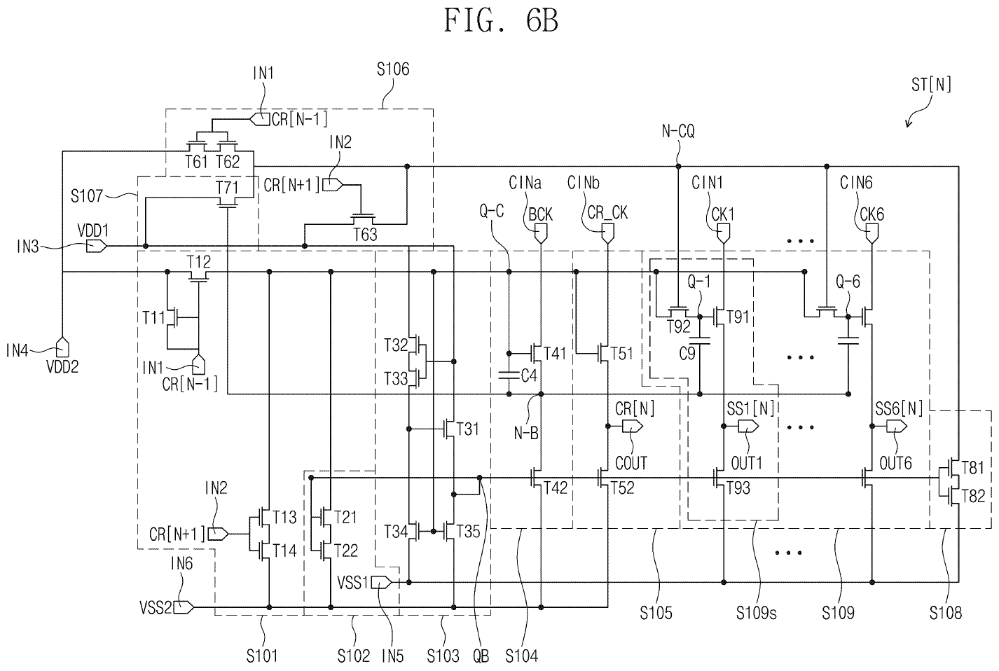

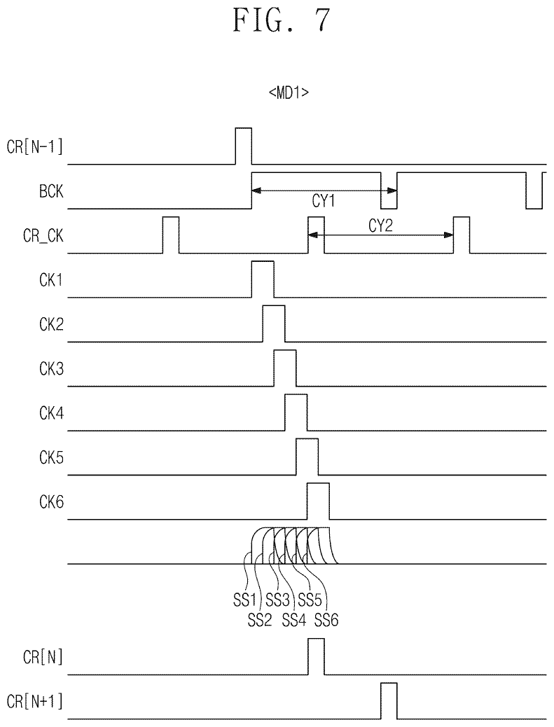

FIG. 7 is a timing diagram for explaining an operation of the stage in a first mode MD1 according to an embodiment of the present disclosure. FIG. 8 is a timing diagram illustrating a plurality of clock signals to explain an operation of the stage in a second mode MD2 according to an embodiment of the present disclosure.

Referring to FIGS. 1, 7, and 8, the display panel DP may selectively operate in the first mode MD1 or the second mode MD2. For example, the first mode MD1 may be a normal driving mode in which the display panel DP operates at a first frequency, and the second mode MD2 may be a high-frequency driving mode in which the display panel DP operates at a second frequency which is higher than the first frequency. For example, the first frequency may be 240 Hz, and the second frequency may be 480 Hz. However, the first frequency and the second frequency described above are merely illustrative and are not particularly limited to the examples.

Referring to FIG. 7, a first carry signal CR[N−1], a second carry signal CR[N], a third carry signal CR[N+1], a boost clock signal BCK, a carry clock signal CR_CK, and first to sixth clock signals CK1, CK2, CK3, CK4, CK5, and CK6 in the first mode MD1 are illustrated as an example.

Referring to FIG. 8, a first carry signal CR[N−1], a second carry signal CR[N], a third carry signal CR[N+1], a boost clock signal BCKa, a carry clock signal CR_CKa, and first to sixth clock signals CK1a, CK2a, CK3a, CK4a, CK5a, and CK6a in the second mode MD2 are illustrated as an example.

Referring to FIGS. 7 and 8 together, the period CY1 of the boost clock signal BCK in the first mode MD1 may be longer than the period CYla of the boost clock signal BCKa in the second mode MD2. For example, the period CY1 may be twice the period CYla. In addition, the period CY2 of the carry clock signal CR_CK in the first mode MD1 may be longer than the period CY2a of the carry clock signal CR_CKa in the second mode MD2. For example, the period CY2 may be twice the period CY2a. That is, the period of clocks may be decreased in the second mode MD2.

According to an embodiment of the present disclosure, at least some of the plurality of scan lines may be simultaneously driven (e.g., activated) for low-power driving or high-speed driving. For example, two scan lines may be simultaneously driven in the second mode MD2. Thus, the second mode MD2 may be referred to as a dual line gate driving mode. In an embodiment of the present disclosure, the first mode MD1 may be a high-resolution mode, and the second mode MD2 may be a high-refresh rate mode.

In the first mode MD1, the first to sixth clock signals CK1, CK2, CK3, CK4, CK5, and CK6 may have different phases. That is, the first to sixth clock signals CK1, CK2, CK3, CK4, CK5, and CK6 may have waveforms shifted from one another by a certain interval. Correspondingly, the first to sixth scan signals SS1, SS2, SS3, SS4, SS5, and SS6 which are output in synchronization with the first to sixth clock signals CK1, CK2, CK3, CK4, CK5, and CK6 may have different phases. The first to sixth scan signals SS1, SS2, SS3, SS4, SS5, and SS6 may be referred to as first mode scan signals.

For example, the first to sixth scan signals SS1, SS2, SS3, SS4, SS5, and SS6 may be first scan signals (or, referred to as first-type scan signals) provided through the first-type scan lines SCLs (refer to FIG. 5), respectively. For example, the first to sixth scan signals SS1, SS2, SS3, SS4, SS5, and SS6 may be second scan signals (or, referred to as second-type scan signals) provided through the second-type scan lines SSLs (refer to FIG. 5), respectively.

In the second mode MD2, some of the first to sixth clock signals CK1a, CK2a, CK3a, CK4a, CK5a, and CK6a may have the same phase. For example, the first clock signal CK1a and the second clock signal CK2a may have the same waveform as each other. The third clock signal CK3a may have a waveform shifted by a certain time with respect to the first clock signal CK1a, and the third clock signal CK3a and the fourth clock signal CK4a may have the same waveform as each other. The fifth clock signal CK5a and the sixth clock signal CK6a may have a waveform shifted by a certain time with respect to the third clock signal CK3a and the fourth clock signal CK4a, and the fifth clock signal CK5a and the sixth clock signal CK6a may have the same waveform as each other.

In the second mode MD2, some scan signal among the first to sixth scan signals SS1a, SS2a, SS3a, SS4a, SS5a, and SS6a which are output in synchronization with the first to sixth clock signals CK1a, CK2a, CK3a, CK4a, CK5a, and CK6a may have the same waveform having the same phase as the other scan signal. For example, in an embodiment, the first scan signal SS1a and the second scan signal SS2a may overlap each other and may have substantially the same waveform. In this case, the data voltage DS (refer to FIG. 6B) may be simultaneously provided to a row of pixels receiving the first scan signal SS1a and a row of pixels receiving the second scan signal SS2a in the second mode MD2.

The third scan signal SS3a and the fourth scan signal SS4a may overlap each other and may have substantially the same waveform. The fifth scan signal SS5a and the sixth scan signal SS6a may overlap each other and may have substantially the same waveform. The first to sixth scan signals SS1a, SS2a, SS3a, SS4a, SS5a, and SS6a may be referred to as second mode scan signals.

For example, the first to sixth scan signals SS1a, SS2a, SS3a, SS4a, SS5a, and SS6a may be first scan signals (or, referred to as first-type scan signals) provided through the first-type scan lines SCLs (refer to FIG. 5), respectively. For example, the first to sixth scan signals SS1a, SS2a, SS3a, SS4a, SS5a, and SS6a may be second scan signals (or, referred to as second-type scan signals) provided through the second-type scan lines SSLs (refer to FIG. 5), respectively.

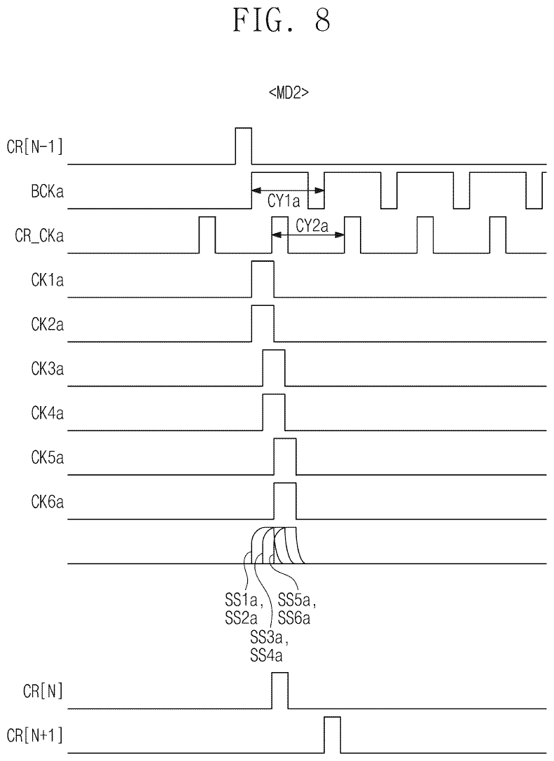

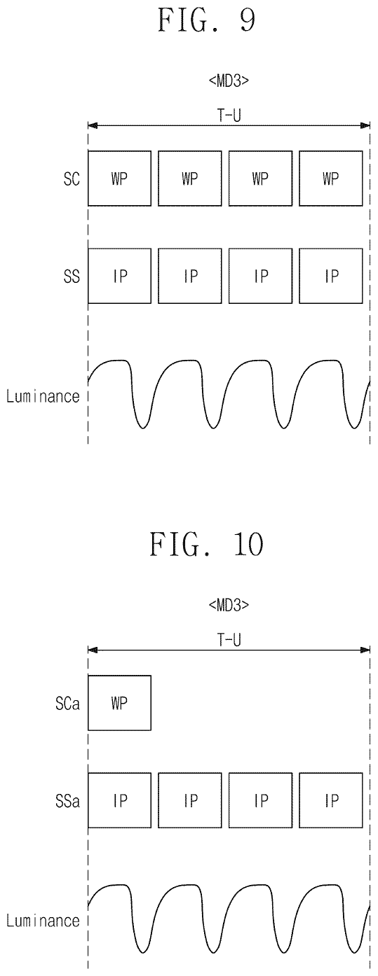

FIG. 9 is a view illustrating activation states of a first-type scan signal SC and a second-type scan signal SS and a change in luminance according to an embodiment of the present disclosure. FIG. 10 is a view illustrating activation states of a first-type scan signal SCa and a second-type scan signal SSa and a change in luminance according to an embodiment of the present disclosure. The first-type scan signal SC and the first-type scan signal SCa may be signals provided to the i-th first-type scan line SCLi illustrated in FIG. 4, and the second-type scan signal SS and the second-type scan signal SSa may be signals provided to the i-th second-type scan line SSLi illustrated in FIG. 4.

Referring to FIGS. 1, 9, and 10, the display panel DP may operate in a mode driven at a variable frame frequency (hereinafter, referred to as the third mode). For example, the variable frame frequency may be variously changed in the range of 1 Hz to 240 Hz, but the range of the variable frame frequency is not particularly limited thereto. FIG. 9 illustrates the first-type scan signal SC, the second-type scan signal SS, and the luminance of the display panel DP when the display panel DP is driven at a frequency of 240 Hz, and FIG. 10 illustrates the first-type scan signal SCa, the second-type scan signal SSa, and the luminance of the display panel DP when the display panel DP is driven at a frequency of 60 Hz.

Referring to FIGS. 9 and 10, when the display panel DP is driven at a frequency of 240 Hz, the first-type scan signal SC may include four write cycle periods WP during a unit time T-U, and the second-type scan signal SS may include four initialization cycle periods IP during a unit time T-U. In addition, when the display panel DP is driven at a frequency of 60 Hz, the first-type scan signal SCa may include one write cycle period WPa during a unit time T-U, and the second-type scan signal SSa may include four initialization cycle periods IP during a unit time T-U.

In the write cycle period WP or WPa, the first-type scan signal SC or SCa may have a waveform in which a logic high level and a logic low level are alternately repeated, and in the remaining periods other than the write cycle period WP or WPa, the first-type scan signal SC or SCa may have a logic low level. In addition, in the initialization cycle periods IP, the second-type scan signal SS or SSa may have a waveform in which a logic high level and a logic low level are alternately repeated.

Referring to FIG. 5 together, the plurality of first-type stages SC-ST1, SC-ST2, and SC-ST3 of the first-type scan drive circuit SCD that generate the first-type scan signal SC or SCa may be separated from the plurality of second-type stages SS-ST1, SS-ST2, and SS-ST3 of the second-type scan drive circuit SSD that generate the second-type scan signal SS or SSa. Accordingly, an operation of the first-type scan signal SC or SCa and an operation of the second-type scan signal SS or SSa may be independently performed from each other. As a result, the number of initialization cycle periods IP within the unit time T-U may be adjusted irrespective of the operating frequency of the display panel DP. In this case, a difference in optical waveform depending on the operating frequency of the display panel DP may be reduced, and thus a luminance difference depending on the operating frequency of the display panel DP may be reduced. That is, the image display quality of the display panel DP may be improved.

The driving modes described with reference to FIGS. 7, 8, 9, and 10 may be applied to the display panel DP in various combinations. For example, in an embodiment of the present disclosure, the display panel DP may operate in one of the first mode MD1, the second mode MD2, and the third mode MD3. Accordingly, the display panel DP may operate in the combination of the first mode MD1, which may correspond to a mode in which the display panel DP is driven at 240 Hz, and the third mode MD3. For example, in an embodiment of the present disclosure, the display panel DP may operate in one of the first mode MD1 and the third mode MD3. In this case, the first mode MD1 may be a normal driving mode in which the display panel DP is driven at a fixed frequency, and the third mode MD3 may be a variable driving mode in which the display panel DP is driven at a variable frequency. For example, in an embodiment of the present disclosure, the display panel DP may operate in one of the first mode MD1 and the second mode MD2. For example, in an embodiment of the present disclosure, the display panel DP may operate only in the first mode MD1. For example, in an embodiment of the present disclosure, the display panel DP may operate only in the third mode MD3.

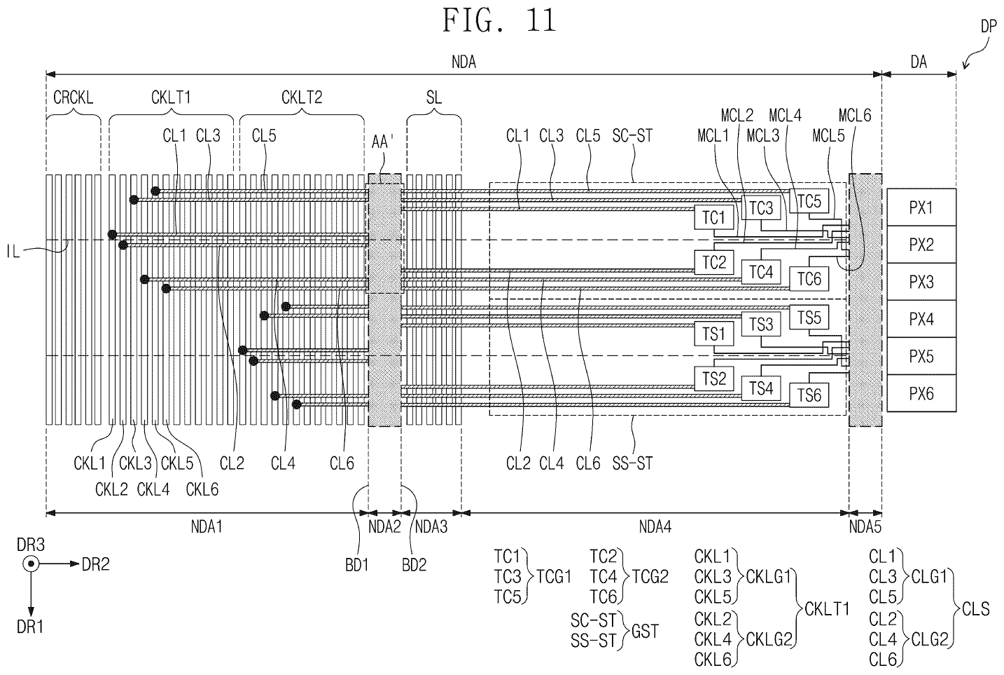

FIG. 11 is a plan view of a portion of the display panel DP according to an embodiment of the present disclosure.

Referring to FIG. 11, the display panel DP may include a plurality of pixels PX1, PX2, PX3, PX4, PX5, and PX6, a group stage GST, a plurality of clock lines CKLT1 and CKLT2, a plurality of connecting lines CLS, a plurality of carry clock lines CRCKL, and a plurality of signal lines SL.

The plurality of pixels PX1, PX2, PX3, PX4, PX5, and PX6 may be disposed in the display area DA. The pixels PX1, PX2, PX3, PX4, PX5, and PX6 may be arranged in the first direction DR1. That is, the pixels PX1, PX2, PX3, PX4, PX5, and PX6 may be arranged in different rows. The pixels PX1, PX2, PX3, PX4, PX5, and PX6 may include the first pixel PX1, the second pixel PX2, the third pixel PX3, the fourth pixel PX4, the fifth pixel PX5, and the sixth pixel PX6 sequentially arranged in the first direction DR1.

The first to sixth pixels PX1, PX2, PX3, PX4, PX5, and PX6 may receive scan signals provided from the group stage GST. For example, the group stage GST may include a first-type stage SC-ST and a second-type stage SS-ST. The first-type stage SC-ST may provide first-type scan signals to first-type scan lines, and the second-type stage SS-ST may provide second-type scan signals to second-type scan lines.

The non-display area NDA may be divided into a plurality of areas. For example, the non-display area NDA may include a first non-display area NDA1, a second non-display area NDA2, a third non-display area NDA3, a fourth non-display area NDA4, and a fifth non-display area NDA5. The first to fifth non-display areas NDA1, NDA2, NDA3, NDA4, and NDA5 may be sequentially defined in the second direction DR2 toward the display area DA.

The carry clock lines CRCKL may be disposed in the first non-display area NDA1. Each of the carry clock lines CRCKL may be a line that provides the carry clock signal CR_CK and the boost clock signal BCK illustrated in FIG. 6B.

The clock lines CKLT1 and CKLT2 may be disposed in the first non-display area NDA1. The clock lines CKLT1 and CKLT2 may include the first-type clock lines CKLT1 and the second-type clock lines CKLT2. For example, some of the first-type clock lines CKLT1 may be lines that transfer the first to sixth clock signals CK1, CK2, CK3, CK4, CK5, and CK6 (refer to FIG. 6A) to the first-type stage SC-ST, and some of the second-type clock lines CKLT2 may be lines that transfer the first to sixth clock signals CK1, CK2, CK3, CK4, CK5, and CK6 (refer to FIG. 6A) to the second-type stage SS-ST.

The first-type clock lines CKLT1 may include a first clock line CKL1, a second clock line CKL2, a third clock line CKL3, a fourth clock line CKLA, a fifth clock line CKL5, and a sixth clock line CKL6. Each of the first to sixth clock lines CKL1, CKL2, CKL3, CKL4, CKL5, and CKL6 may extend in the first direction DR1, and the first to sixth clock lines CKL1, CKL2, CKL3, CKL4, CKL5, and CKL6 may be arranged in the second direction DR2. For example, another six clock lines arranged on the right side of the sixth clock line CKL6 among the first-type clock lines CKLT1 may be lines that transfer clock signals to a first-type stage SC-ST of a next group stage GST which is arranged in the first direction after the group stage GST illustrated in FIG. 11.

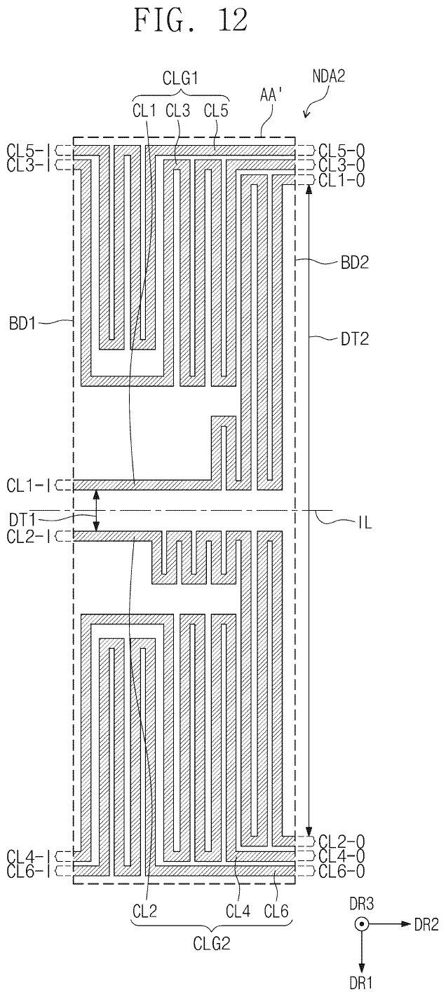

The second non-display area NDA2 may be an equivalent resistance design area. An enlarged view of some of the lines disposed in the second non-display area NDA2 is illustrated in FIG. 12, and description of the equivalent resistance design area will be given below.

The signal lines SL may be disposed in the third non-display area NDA3. Each of the signal lines SL may be a line that transfers a power supply voltage and other signals.

The group stage GST may be disposed in the fourth non-display area NDA4. The first-type stage SC-ST of the group stage GST may include a plurality of transistors TC1, TC2, TC3, TC4, TC5, and TC6 that output a plurality of first-type scan signals to the first to sixth pixels PX1, PX2, PX3, PX4, PX5, and PX6, respectively. The second-type stage SS-ST of the group stage GST may include a plurality of transistors TS1, TS2, TS3, TS4, TS5, and TS6 that output a plurality of second-type scan signals to the first to sixth pixels PX1, PX2, PX3, PX4, PX5, and PX6, respectively.

For example, the plurality of transistors TC1, TC2, TC3, TC4, TC5, and TC6 may correspond to the six first transistors T91 of the six output circuits S109s illustrated in FIG. 6B. For example, the plurality of transistors TS1, TS2, TS3, TS4, TS5, and TS6 may correspond to the six first transistors T91 of the six output circuits S109s illustrated in FIG. 6B. Hereinafter, the plurality of transistors TC1, TC2, TC3, TC4, TC5, and TC6 of the first-type stage SC-ST will be described in detail, and description of the plurality of transistors TS1, TS2, TS3, TS4, TS5, and TS6 of the second-type stage SS-ST will be omitted because the plurality of transistors TS1, TS2, TS3, TS4, TS5, and TS6 have substantially the same configurations as the plurality of transistors TC1, TC2, TC3, TC4, TC5, and TC6.

The transistors TC1, TC2, TC3, TC4, TC5, and TC6 may include the first transistor TC1, the second transistor TC2, the third transistor TC3, the fourth transistor TC4, the fifth transistor TC5, and the sixth transistor TC6 that correspond to the first to sixth pixels PX1, PX2, PX3, PX4, PX5, and PX6 in a one-to-one manner.

According to an embodiment of the present disclosure, the first to sixth transistors TC1, TC2, TC3, TC4, TC5, and TC6 may be disposed in at least two rows to reduce the width of the non-display area NDA, for example, in the second direction DR2. For example, the first to sixth transistors TC1, TC2, TC3, TC4, TC5, and TC6 may not be continuously arranged in the same row, but may be arranged such that some of the first to sixth transistors TC1, TC2, TC3, TC4, TC5, and TC6 and the other transistors face each other. Accordingly, the width of the non-display area NDA in the second direction DR2 may be reduced.

The first to sixth transistors TC1, TC2, TC3, TC4, TC5, and TC6 may be electrically connected to the first to sixth clock lines CKL1, CKL2, CKL3, CKLA, CKL5, and CKL6. For example, the first to sixth transistors TC1, TC2, TC3, TC4, TC5, and TC6 and the first to sixth clock lines CKL1, CKL2, CKL3, CKL4, CKL5, and CKL6 may be electrically connected through the connecting lines CLS. Accordingly, the connecting lines CLS may transfer clock signals received from the first to sixth clock lines CKL1, CKL2, CKL3, CKL4, CKL5, and CKL6 to the first to sixth transistors TC1, TC2, TC3, TC4, TC5, and TC6.

The connecting lines CLS may include a first connecting line CL1, a second connecting line CL2, a third connecting line CL3, a fourth connecting line CLA, a fifth connecting line CL5, and a sixth connecting line CL6 that are connected to the first to sixth transistors TC1, TC2, TC3, TC4, TC5, and TC6 in a one-to-one correspondence.

The first connecting line CL1 may be connected between the first clock line CKL1 and the first transistor TC1, the second connecting line CL2 may be connected between the second clock line CKL2 and the second transistor TC2, the third connecting line CL3 may be connected between the third clock line CKL3 and the third transistor TC3, the fourth connecting line CL4 may be connected between the fourth clock line CKLA and the fourth transistor TC4, the fifth connecting line CL5 may be connected between the fifth clock line CKL5 and the fifth transistor TC5, and the sixth connecting line CL6 may be connected between the sixth clock line CKL6 and the sixth transistor TC6.

The first to sixth transistors TC1, TC2, TC3, TC4, TC5, and TC6 may be grouped as a plurality of first group transistors TCG1 connected to the (2N−1)th pixels (here, N is an integer of 1 or more) in the first direction DR1 among the pixels PX1, PX2, PX3, PX4, PX5 and PX6, and a plurality of second group transistors TCG2 connected to the 2N-th pixels in the first direction DR1 among the pixels PX1, PX2, PX3, PX4, PX5, and PX6. The first group transistors TCG1 and the second group transistors TCG2 may be spaced apart from each other with a virtual reference line IL extending in the second direction DR2 between the first group transistors TCG1 and the second group transistors TCG2. The virtual reference line IL may be referred to as a reference line or an extension line.

The first to sixth connecting lines CL1, CL2, CL3, CL4, CL5, and CL6 may be grouped as first group connecting lines CLG1 connected to the first group transistors TCG1 and second group connecting lines CLG2 connected to the second group transistors TCG2. The first group connecting lines CLG1 and second group connecting lines CLG2 may be spaced apart from each other with the virtual reference line IL extending in the second direction DR2 between the first group connecting lines CLG1 and the second group connecting lines CLG2.

The first group transistors TCG1 may include the first transistor TC1, the third transistor TC3, and the fifth transistor TC5, and the second group transistors TCG2 may include the second transistor TC2, the fourth transistor TC4, and the sixth transistor TC6. The first group connecting lines CLG1 may include the first connecting line CL1, the third connecting line CL3, and the fifth connecting line CL5, and the second group connecting lines CLG2 may include the second connecting line CL2, the fourth connecting line CL4, and the sixth connecting line CL6.

The first to sixth clock lines CKL1, CKL2, CKL3, CKL4, CKL5, and CKL6 may be grouped as a plurality of first group clock lines CKLG1 including the first clock line CKL1, the third clock line CKL3 and the fifth clock line CKL5 electrically connected to the first group connecting lines CLG1, and a plurality of second group clock lines CKLG2 including the second clock line CKL2, the fourth clock line CKLA, and the sixth clock line CKL6 electrically connected to the second group connecting lines CLG2. The first group clock lines CKL1, CKL3, and CKL5 and the second group clock lines CKL2, CKL4, and CKL6 may alternate with one another in the second direction DR2.

According to an embodiment of the present disclosure, the transistors and the connecting lines CL1, CL3, and CL5 connected with the odd-numbered pixels may be disposed above the virtual reference line IL, and the transistors and the connecting lines CL2, CL4, and CL6 connected with the even-numbered pixels may be disposed below the virtual reference line IL.

According to an embodiment of the present disclosure, the first connecting line CL1 and the second connecting line CL2 may be separately disposed above and below the virtual reference line IL. In addition, the first transistor TC1 connected to the first connecting line CL1 and the second transistor TC2 connected to the second connecting line CL2 may be disposed to face each other with respect to the virtual reference line IL. In this case, the difference in resistance between the first connecting line CL1 and the second connecting line CL2 may be reduced to the level of a resistance difference caused by the pitch in the second direction DR2 between the first clock line CKL1 and the second clock line CKL2. That is, the resistance difference between the first connecting line CL1 and the second connecting line CL2 may be reduced.

The third connecting line CL3 and the fourth connecting line CL4 may also be spaced apart from each other with respect to the virtual reference line IL, and the third transistor TC3 and the fourth transistor TC4 may also be disposed to face each other with respect to the virtual reference line IL. In addition, the fifth connecting line CL5 and the sixth connecting line CL6 may also be spaced apart from each other with respect to the virtual reference line IL, and the fifth transistor TC5 and the sixth transistor TC6 may also be disposed to face each other with respect to the virtual reference line IL.

According to an embodiment of the present disclosure, equivalent resistance design may be simplified as the connecting lines connected to the clock lines adjacent to each other are spaced apart from each other with respect to the virtual reference line IL. For example, the equivalent resistance design layout of the first connecting line CL1, the third connecting line CL3, and the fifth connecting line CL5 may be similar to, and may be symmetrical to the equivalent resistance design layout of the second connecting line CL2, the fourth connecting line CL4, and the sixth connecting line CL6 with respect to the virtual reference line IL.

In addition, since the first to sixth transistors TC1, TC2, TC3, TC4, TC5, and TC6 are divided into two groups, for example, the first group transistors TCG1 and the second group transistors TCG2, based on the virtual reference line IL, equivalent resistance design may be performed for half of six connecting lines, for example, the first, third, and fifth connecting lines CL1, CL3, and CL5. Accordingly, the area required for the equivalent resistance design may be reduced.

In an embodiment of the present disclosure, the first transistor TC1 and the second transistor TC2 may face each other in the first direction DR1, the third transistor TC3 and the fourth transistor TC4 may face each other in the first direction DR1, and the fifth transistor TC5 and the sixth transistor TC6 may face each other in the first direction DR1. Although FIG. 11 illustrates an example that the transistors facing each other are completely aligned with each other and arranged in a symmetrical form, the present disclosure is not particularly limited thereto. For example, the first, third, and fifth transistors TC1, TC3, and TC5 may be shifted by the pitch between the first clock line CKL1 and the second clock line CKL2 such that the first, third, and fifth transistors TC1, TC3, and TC5 are closer to the second non-display area NDA2 than the second, fourth, and sixth transistors TC2, TC4, and TC6.

In an embodiment, the third transistor TC3 may be disposed between the first transistor TC1 and the fifth transistor TC5, and the fourth transistor TC4 may be disposed between the second transistor TC2 and the sixth transistor TC6.

The first transistor TC1, the third transistor TC3, and the fifth transistor TC5 may be sequentially arranged in a direction away from the first-type clock lines CKLT1. In addition, the second transistor TC2, the fourth transistor TC4, and the sixth transistor TC6 may also be sequentially arranged in the direction away from the first-type clock lines CKLT1.

The gap between the fifth transistor TC5 and the sixth transistor TC6 may be greater than the gap between the third transistor TC3 and the fourth transistor TC4. The gap between the third transistor TC3 and the fourth transistor TC4 may be greater than the gap between the first transistor TC1 and the second transistor TC2.

That is, the first transistor TC1, the third transistor TC3, and the fifth transistor TC5 may be arranged in a step shape, and the second transistor TC2, the fourth transistor TC4, and the sixth transistor TC6 may also be arranged in the step shape. By arranging the first transistor TC1, the third transistor TC3 and the fifth transistor TC5 in a step-wise, and the second transistor TC2, the fourth transistor TC4 and the sixth transistor TC6 in a step-wise, the first to sixth connecting lines CL1, CL2, CL3, CL4, CL5, and CL6 extending in the second direction DR2 may be easily connected to the corresponding first to sixth transistors TC1, TC2, TC3, TC4, TC5, and TC6.

The display panel DP may further include a first intermediate connecting line MCL1, a second intermediate connecting line MCL2, a third intermediate connecting line MCL3, a fourth intermediate connecting line MCL4, a fifth intermediate connecting line MCL5, and a sixth intermediate connecting line MCL6 that are connected to the first to sixth transistors TC1, TC2, TC3, TC4, TC5, and TC6 in a one-to-one manner. The first to sixth intermediate connecting lines MCL1, MCL2, MCL3, MCLA, MCL5, and MCL6 may extend toward the first to sixth pixels PX1, PX2, PX3, PX4, PX5, and PX6.

FIG. 12 is an enlarged plan view illustrating area AA′ of FIG. 11 according to an embodiment of the present disclosure.

Referring to FIGS. 11 and 12, the first to sixth connecting lines CL1, CL2, CL3, CL4, CL5, and CL6 may be electrically connected to the first to sixth clock lines CKL1, CKL2, CKL3, CKL4, CKL5, and CKL6 in a one-to-one manner and may extend toward the group stage GST.

The clock lines CRCKL, CKLT1, and CKLT2 may be disposed in the first non-display area NDA1, and the group stage GST may be disposed in the fourth non-display area NDA4. The first to sixth connecting lines CL1, CL2, CL3, CL4, CL5, and CL6 may have a bent shape in the second non-display area NDA2. The first non-display area NDA1 may be referred to as a first area, the fourth non-display area NDA4 may be referred to as a second area, and the second non-display area NDA2 may be referred to as a third area.

The second non-display area NDA2 may include a first boundary BD1 adjacent to the first non-display area NDA1 and extending in the first direction DR1, and a second boundary BD2 closer to the fourth non-display area NDA4 than the first non-display area NDA1 and extending in the first direction DR1.

The first connecting line CL1 may include a first input end portion CL1-I overlapping the first boundary BD1 and a first output end portion CL1-O overlapping the second boundary BD2. The second connecting line CL2 may include a second input end portion CL2-I overlapping the first boundary BD1 and a second output end portion CL2-O overlapping the second boundary BD2. The third connecting line CL3 may include a third input end portion CL3-I overlapping the first boundary BD1 and a third output end portion CL3-O overlapping the second boundary BD2. The fourth connecting line CL4 may include a fourth input end portion CL4-I overlapping the first boundary BD1 and a fourth output end portion CLA-O overlapping the second boundary BD2. The fifth connecting line CL5 may include a fifth input end portion CL5-I overlapping the first boundary BD1 and a fifth output end portion CL5-O overlapping the second boundary BD2. The sixth connecting line CL6 may include a sixth input end portion CL6-I overlapping the first boundary BD1 and a sixth output end portion CL6-O overlapping the second boundary BD2.

According to an embodiment of the present disclosure, at least some of the first to sixth input end portions CL1-I, CL2-I, CL3-I, CL4-I, CL5-I, and CL6-I and the first to sixth output end portions CL1-O, CL2-O, CL3-O, CL4-O, CL5-O, and CL6-O may not be aligned when viewed in the second direction DR2. For example, when two positions are arranged on the same axis extending in the first direction DR1, the two positions are defined as “aligned” in the second direction DR2, and when the two positions are not arranged on the same axis extending in the first direction DR1, the two positions are defined as “not aligned” in the second direction DR2.

For example, in a case in which an input end portion and an output end portion are aligned with each other when viewed in the second direction DR2, the number of linear portions between the input end portion and the output end portion of a corresponding connecting line that extend in the first direction DR1 has to be an even number. However, in a case in which an input end portion and an output end portion are not aligned with each other when viewed in the second direction DR2, the number of linear portions between the input end portion and the output end portion of a corresponding connecting line that extend in the first direction DR1 may be an odd number. That is, since the number of linear portions between the input end portion and the output end portion of at least some of the first to sixth connecting lines CL1 to CL6 does not necessarily have to be an even number, the degree of freedom in design may be improved. In addition, since the number of linear portions between the input end portion and the output end portion of at least some of the first to sixth connecting lines CL1 to CL6 does not necessarily have to be an even number, the width of the second non-display area NDA2 in the second direction DR1 may be further reduced.

According to an embodiment of the present disclosure, the third, fourth, fifth, and sixth input end portions CL3-I, CL4-I, CL5-I, and CL6-I may be aligned with the third, fourth, fifth, and sixth output end portions CL3-O, CL4-O, CL5-O, and CL6-O when viewed in the second direction DR2, and the first and second input end portions CL1-I and CL2-I may not be aligned with the first and second output end portions CL1-O and CL2-O when viewed in the second direction DR2. Accordingly, the first input end portion CL1-I of the first connecting line CL1 that overlaps the first boundary BD1 and the first output end portion CL1-O of the first connecting line CL1 that overlaps the second boundary BD2 may not overlap each other in the second direction DR2.

According to an embodiment of the present disclosure, the first distance DT1 between the first connecting line CL1 and the second connecting line CL2 at the first boundary BD1 may be less than the second distance DT2 between the first connecting line CL1 and the second connecting line CL2 at the second boundary BD2.

According to an embodiment of the present disclosure, the positions of at least one of the first group connecting lines CLG1 at the first boundary BD1 and the second boundary BD2 may be aligned with each other, and the positions of at least one other of the first group connecting lines CLG1 at the first boundary BD1 and the second boundary BD2 may be different from each other.

In addition, the first distance DT1 between the first group connecting lines CLG1 and the second group connecting lines CLG2 at the first boundary BD1 may be less than the second distance DT2 between the first group connecting lines CLG1 and the second group connecting lines CLG2 at the second boundary BD2.

In the second non-display area NDA2, the connecting lines that connect the second-type stage SS-ST to the second-type clock lines CKLT2 may also have a similar layout to those of the first to sixth connecting lines CL1, CL2, CL3, CL4, CL5, and CL6. That is, according to an embodiment of the present disclosure, the equivalent resistance design area of the connecting lines that transfer signals to the first-type stage SC-ST and the equivalent resistance design area of the connecting lines that transfer signals to the second-type stage SS-ST may overlap each other in the first direction DR1. For example, the equivalent resistance design area of the connecting lines that transfer signals to the first-type stage SC-ST and the equivalent resistance design area of the connecting lines that transfer signals to the second-type stage SS-ST may be disposed in the second non-display area NDA2. Accordingly, the width of the non-display area NDA in the second direction DR2 may be further reduced.

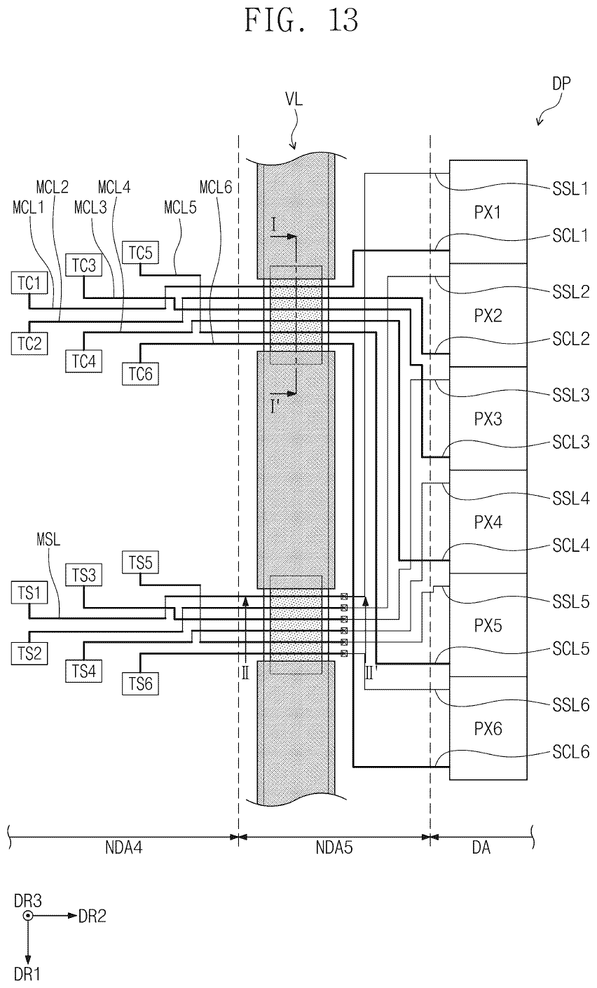

FIG. 13 is an enlarged plan view illustrating a portion of the display panel DP according to an embodiment of the present disclosure.

Referring to FIGS. 11 and 13, a voltage line VL may be disposed in the fifth non-display area NDA5. That is, the voltage line VL may be disposed between the group stage GST and the first to sixth pixels PX1, PX2, PX3, PX4, PX5, and PX6. The voltage line VL may be electrically connected to the fifth input terminal IN5 illustrated in FIG. 6B and may receive the first low voltage VSS1. However, this is only an example, and the position of the voltage line VL is not limited thereto.

The first to sixth intermediate connecting lines MCL1, MCL2, MCL3, MCLA, MCL5, and MCL6 may be sequentially arranged in the first direction DR1 in the area overlapping the voltage line VL. That is, the first to sixth intermediate connecting lines MCL1, MCL2, MCL3, MCLA, MCL5, and MCL6 may extend from the first, third, and fifth transistors TC1, TC3, and TC5 and the second, fourth, and sixth transistors TC2, TC4, and TC6 that are spaced apart from each other with respect to the virtual reference line IL and may be aligned to correspond to the order of the first to sixth pixels PX1, PX2, PX3, PX4, PX5, and PX6.

Signals output from the first to sixth transistors TC1, TC2, TC3, TC4, TC5, and TC6 may be output to the first to sixth scan lines SCL1, SCL2, SCL3, SCLA, SCL5, and SCL6 connected to the first to sixth pixels PX1, PX2, PX3, PX4, PX5, and PX6. In addition, signals output from the first to sixth transistors TS1, TS2, TS3, TS4, TS5, and TS6 may be output to the first to sixth scan lines SSL1, SSL2, SSL3, SSLA, SSL5, and SSL6 connected to the first to sixth pixels PX1, PX2, PX3, PX4, PX5, and PX6.

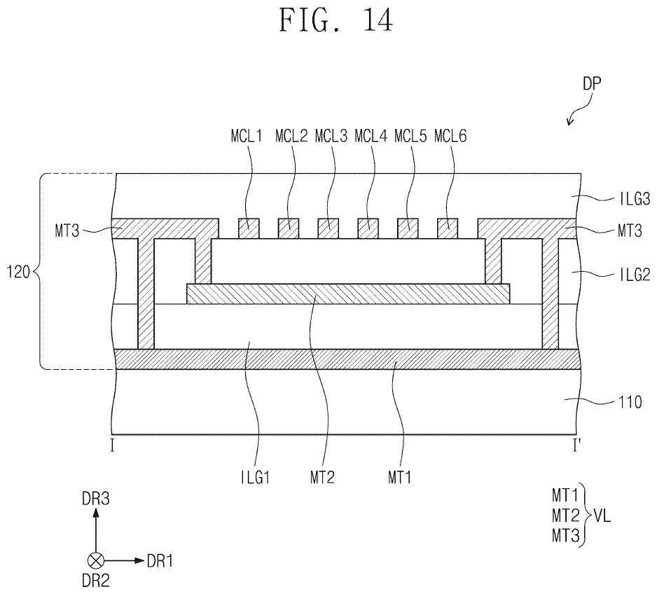

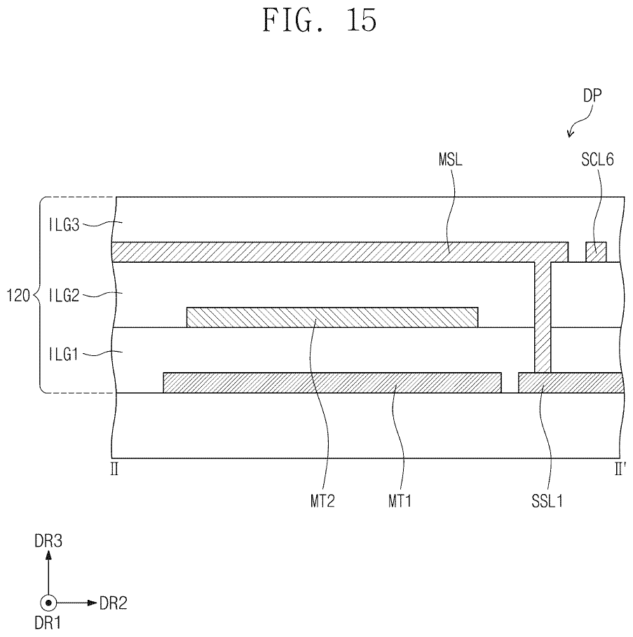

FIG. 14 is a sectional view of the display panel taken along a line I-I′ of FIG. 13 according to an embodiment of the present disclosure. FIG. 15 is a sectional view of the display panel taken along a line II-II′ of FIG. 13 according to an embodiment of the present disclosure.

Referring to FIGS. 13, 14, and 15, the display panel DP may further include a base layer 110 and a circuit layer 120. Although FIGS. 13 and 14 only illustrate some components of the display panel DP, the display panel DP may further include a light emitting element layer including the light emitting element ED (refer to FIG. 4) and an encapsulation layer that covers the light emitting element layer.

The base layer 110 may be a member that provides a base surface on which the circuit layer 120 is disposed. The base layer 110 may have a single-layer structure or a multi-layer structure. The base layer 110 may be a glass substrate, a metal substrate, a silicon substrate, or a polymer substrate, but the type of the base layer 110 is not particularly limited thereto.

The circuit layer 120 may be disposed on the base layer 110. The circuit layer 120 may include a first intermediate insulating layer ILG1, a second intermediate insulating layer ILG2, and a third intermediate insulating layer ILG3. Each of the first intermediate insulating layer ILG1, the second intermediate insulating layer ILG2, and the third intermediate insulating layer ILG3 may include one or more insulating layers, and each of the one or more insulating layers may be an inorganic insulating layer or an organic insulating layer.

The voltage line VL may have a multi-layer structure including two or more layers. The voltage line VL may include a first wiring pattern MT1, a second wiring pattern MT2, and a third wiring pattern MT3. The first wiring pattern MT1, the second wiring pattern MT2, and the third wiring pattern MT3 may be electrically connected with one another.

Referring to FIG. 14, the wiring pattern MT1 may be disposed on the base layer 110. The first intermediate insulating layer ILG1 may be disposed on the base layer 110 and may cover the first wiring pattern MT1. The second wiring pattern MT2 may be disposed on the first intermediate insulating layer ILG1. The second intermediate insulating layer ILG2 may be disposed on the first intermediate insulating layer ILG1 and may cover the second wiring pattern MT2. The third wiring pattern MT3 and the first to sixth intermediate connecting lines MCL1, MCL2, MCL3, MCL4, MCL5, and MCL6 may be disposed on the second intermediate insulating layer ILG2. The third intermediate insulating layer ILG3 may be disposed on the second intermediate insulating layer ILG2 and may cover the third wiring pattern MT3 and the first to sixth intermediate connecting lines MCL1, MCL2, MCL3, MCLA, MCL5, and MCL6.

Referring to FIGS. 13 and 14, the first to sixth scan lines SCL1, SCL2, SCL3, SCL4, SCL5, and SCL6 may be connected to the first to sixth intermediate connecting lines MCL1, MCL2, MCL3, MCLA, MCL5, and MCL6 in a one-to-one manner and may be disposed on the same layer as the first to sixth intermediate connecting lines MCL1, MCL2, MCL3, MCLA, MCL5, and MCL6.

Referring to FIG. 15, an intermediate connecting line MSL connected from the first transistor TS1 may be disposed between the second intermediate insulating layer ILG2 and the third intermediate insulating layer ILG3. The first scan line SSL1 may be disposed on a layer different from the layer on which the intermediate connecting line MSL is disposed. The intermediate connecting line MSL may extend through the second intermediate insulating layer ILG2 and the first intermediate insulating layer ILG1 and may be connected to the first scan line SSL1.

Although FIG. 15 illustrates an example in which the first scan line SSL1 is disposed between the first intermediate insulating layer ILG1 and the base layer 110, the position of the first scan line SSL1 is not particularly limited thereto. For example, the first scan line SSL1 may be disposed between the first intermediate insulating layer ILG1 and the second intermediate insulating layer ILG2.

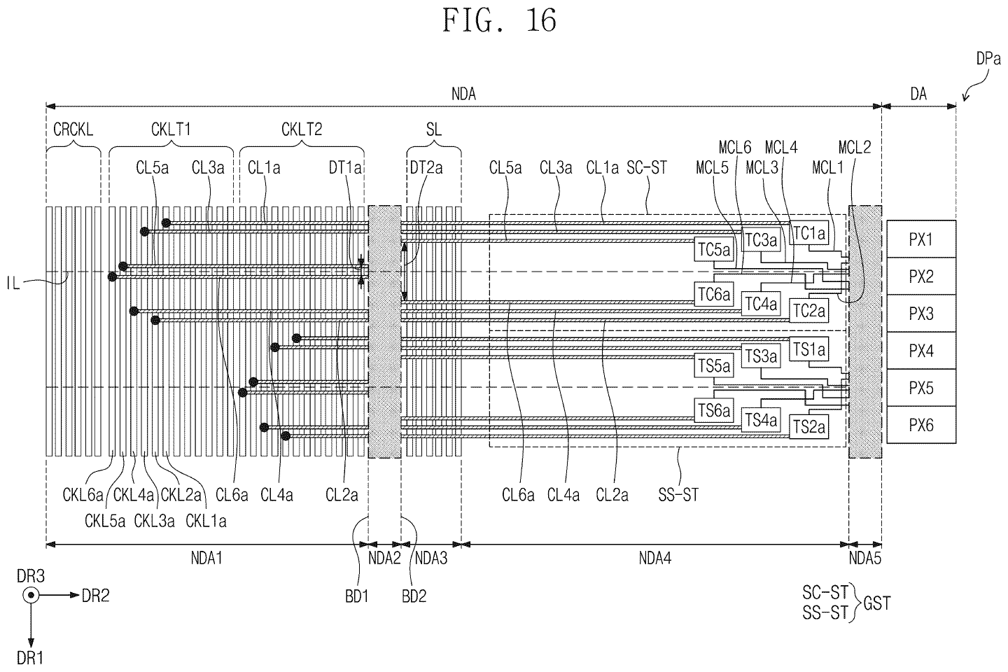

FIG. 16 is a plan view of a portion of a display panel DPa according to an embodiment of the present disclosure. In describing FIG. 16, components identical to the components described with reference to FIG. 11 will be identified with identical reference numerals, and description thereabout will be omitted.

Referring to FIG. 16, each of first to sixth clock lines CKL1a, CKL2a, CKL3a, CKL4a, CKL5a, and CKL6a may extend in the first direction DR1, and the first to sixth clock lines CKL1a, CKL2a, CKL3a, CKL4a, CKL5a, and CKL6a may be sequentially arranged in the direction opposite to the second direction DR2. For example, the first to sixth clock lines CKL1a, CKL2a, CKL3a, CKL4a, CKL5a, and CKL6a may be sequentially arranged in a direction away from the group stage GST. That is, the sixth clock line CKL6a may be disposed closer to a carry clock lines CRCKL, and the first clock line CKL1a may be disposed closer to second-type clock lines CKLT2.

A first transistor TC1a, a third transistor TC3a, and a fifth transistor TC5a may be sequentially arranged in a direction toward the first to sixth clock lines CKL1a, CKL2a, CKL3a, CKL4a, CKL5a, and CKL6a. In addition, a second transistor TC2a, a fourth transistor TC4a, and a sixth transistor TC6a may also be sequentially arranged in the direction toward the first to sixth clock lines CKL1a, CKL2a, CKL3a, CKL4a, CKL5a, and CKL6a. That is, the first transistor TC1a and the second transistor TC2a are disposed closer to a fifth non-display area NDA5, and the fifth transistor TC5a and the sixth transistor TC6a are disposed closer to the second non-display area NDA2. First to sixth transistors TSla, TS2a, TS3a, TS4a, TS5a, and TS6a may also have the same arrangement as the first to sixth transistors TC1a, TC2a, TC3a, TC4a, TC5a, and TC6a.

First to sixth connecting lines CL1a, CL2a, CL3a, CL4a, CL5a, and CL6a may be electrically connected to the first to sixth clock lines CKL1a, CKL2a, CKL3a, CKL4a, CKL5a, and CKL6a in a one-to-one basis and may extend toward the group stage GST. In addition, the first to sixth connecting lines CL1a, CL2a, CL3a, CLAa, CL5a, and CL6a may be electrically connected to the first to sixth transistors TC1a, TC2a, TC3a, TC4a, TC5a, and TC6a in a one-to-one correspondence.

The first distance DT1a between the fifth connecting line CL5a and the sixth connecting line CL6a at the first boundary BD1 may be less than the second distance DT2a between the fifth connecting line CL5a and the sixth connecting line CL6a at the second boundary BD2.

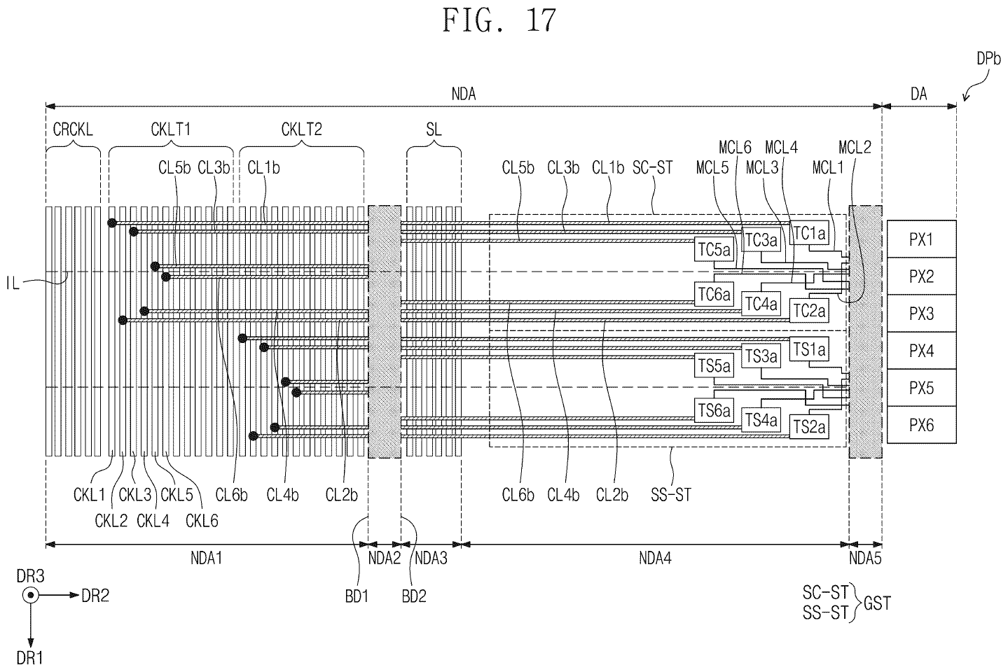

FIG. 17 is a plan view of a portion of a display panel DPb according to an embodiment of the present disclosure. In describing FIG. 17, components identical to the components described with reference FIGS. 11 and 16 will be identified with identical reference numerals.

Referring to FIG. 17, each of the first to sixth clock lines CKL1, CKL2, CKL3, CKL4, CKL5, and CKL6 may extend in the first direction DR1, and the first to sixth clock lines CKL1, CKL2, CKL3, CKL4, CKL5, and CKL6 may be sequentially arranged in the second direction DR2. For example, the first clock line CKL1 may be disposed closer to a carry clock lines CRCKL, and the six clock line CKL6 may be disposed closer to second-type clock lines CKLT2.

The first transistor TC1a, the third transistor TC3a, and the fifth transistor TC5a may be sequentially arranged in a direction toward the first to sixth clock lines CKL1, CKL2, CKL3, CKL4, CKL5, and CKL6. In addition, the second transistor TC2a, the fourth transistor TC4a, and the sixth transistor TC6a may also be sequentially arranged in the direction toward the first to sixth clock lines CKL1, CKL2, CKL3, CKL4, CKL5, and CKL6. That is, the first transistor TC1a and the second transistor TC2a are disposed closer to a fifth non-display area NDA5, and the fifth transistor TC5a and the sixth transistor TC6a are disposed closer to the second non-display area NDA2.

First to sixth connecting lines CL1b, CL2b, CL3b, CL4b, CL5b, and CL6b may be electrically connected to the first to sixth clock lines CKL1, CKL2, CKL3, CKL4, CKL5, and CKL6 in a one-to-one manner and may extend toward the group stage GST. In addition, the first to sixth connecting lines CL1b, CL2b, CL3b, CL4b, CL5b, and CL6b may be electrically connected to the first to sixth transistors TC1a, TC2a, TC3a, TC4a, TC5a, and TC6a in a one-to-one manner.

When FIGS. 16 and 17 are compared with each other, the arrangement direction of the first to sixth clocks lines CKL1a, CKL2a, CKL3a, CKL4a, CKL5a, and CKL6a of FIG. 16 may be different from the arrangement direction of the first to sixth clock lines CKL1, CKL2, CKL3, CKL4, CKL5, and CKL6 of FIG. 17. In this case, deviations in the distances in the second direction DR2 between first ends and second ends of the first to sixth connecting lines CL1a, CL2a, CL3a, CL4a, CL5a, and CL6a illustrated in FIG. 16 may be less than deviations in the distances in the second direction DR2 between first ends and second ends of the first to sixth connecting lines CL1b, CL2b, CL3b, CL4b, CL5b, and CL6b illustrated in FIG. 17. Here, the first ends may correspond to the points where the connecting lines are in contact with the clock lines, and the second ends may correspond to the points where the connecting lines are in contact with the transistors. Thus, according to the embodiment illustrated in FIG. 16, the area of an equivalent resistance design area, for example, the second non-display area NDA2, may be further reduced when compared to that in the embodiment illustrated in FIG. 17.

Referring to FIGS. 16 and 17, the first to sixth transistors TC1a, TC2a, TC3a, TC4a, TC5a, and TC6a may be disposed in at least two rows to reduce the width of the non-display area NDA (refer to FIG. 2), for example, in the second direction DR2. For example, the first to sixth transistors TC1a, TC2a, TC3a, TC4a, TC5a, and TC6a may not be continuously arranged in the same row, but may be arranged such that some of the first to sixth transistors TC1a, TC2a, TC3a, TC4a, TC5a, and TC6a and the other transistors face each other. Accordingly, the width of the non-display area NDA in the second direction DR2 may be reduced.

Furthermore, the connecting lines connected to the clock lines adjacent to one another may be symmetrically disposed with respect to the virtual reference line IL, and thus equivalent resistance design may be simplified. For example, the equivalent resistance design layout of the first, third, and fifth connecting lines CL1a, CL3a, and CL5a or CL1b, CL3b, and CL5b may be similar to, and may be symmetrical to the equivalent resistance design layout of the second, fourth, and sixth connecting lines CL2a, CL4a, and CL6a or CL2b, CL4b, and CL6b.

Moreover, since the first to sixth transistors TC1a, TC2a, TC3a, TC4a, TC5a, and TC6a are divided into two groups based on the virtual reference line IL, equivalent resistance design may be performed for half of six lines, for example, the first, third, and fifth connecting lines CL1a, CL3a, and CL5a or CLIb, CL3b, and CL5b. Accordingly, the area required for the equivalent resistance design, for example, the width in the second direction DR2, may be reduced.

In addition, the equivalent resistance design layout of the connecting lines that transfer signals to the second-type stage SS-ST may also be disposed in the second non-display area NDA2. Accordingly, the equivalent resistance design area of the connecting lines that transfer signals to the first-type stage SC-ST and the equivalent resistance design area of the connecting lines that transfer signals to the second-type stage SS-ST may overlap each other in the first direction DR1. For example, the equivalent resistance design area of the connecting lines that transfer signals to the first-type stage SC-ST and the equivalent resistance design area of the connecting lines that transfer signals to the second-type stage SS-ST may be disposed in the second non-display area NDA2. Thus, the width of the non-display area NDA in the second direction DR2 may be further reduced.

As described above, the display panel may include the plurality of stages disposed in the non-display area, and each of the plurality of stages may include the plurality of transistors. Some of the plurality of transistors and the other transistors may be disposed to face each other. Accordingly, the width of the non-display area of the display panel required for the plurality of transistors may be reduced.

In addition, the display panel may further include the plurality of connecting lines connected to the plurality of transistors in a one-to-one manner. Some of the plurality of connecting lines and the other connecting lines may be spaced apart from each other with respect to the virtual reference line therebetween. Accordingly, the equivalent resistance design may be simplified, and thus the width or area of the equivalent resistance design space may be reduced.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display panel comprising:
a plurality of pixels arranged in a first direction;
a stage including a plurality of transistors connected to the plurality of pixels and outputting a plurality of scan signals to the plurality of pixels;
a plurality of clock lines electrically connected to the stage; and
a plurality of connecting lines connecting the plurality of clock lines to the plurality of transistors,
wherein the plurality of transistors include a plurality of first group transistors connected to (2N−1)th pixels arranged in the first direction, wherein N is an integer, among the plurality of pixels, and a plurality of second group transistors connected to 2N-th pixels arranged in the first direction among the plurality of pixels, and
wherein the plurality of first group transistors and the plurality of second group transistors are spaced apart from each other with respect to a virtual reference line between the first group transistors and the second group transistors, the virtual reference line extending in a second direction crossing the first direction.

2. The display panel of claim 1, wherein the plurality of connecting lines include a plurality of first group connecting lines connected to the plurality of first group transistors and a plurality of second group connecting lines connected to the plurality of second group transistors, and
wherein the plurality of first group connecting lines and the plurality of second group connecting lines are spaced apart from each other with respect to the virtual reference line between the plurality of first group connecting lines and the second group connecting lines.

3. The display panel of claim 2, wherein a first area in which the plurality of clock lines are disposed, a second area in which the stage is disposed, and a third area between the first area and the second area are defined in the display panel, and
wherein the plurality of connecting lines have a bent shape in the third area.

4. The display panel of claim 3, wherein the third area includes a first boundary adjacent to the first area and extending in the first direction, and a second boundary adjacent to the second area and extending in the first direction, and
wherein positions of at least one of the first group connecting lines at the first boundary and the second boundary are aligned with each other in the second direction, and positions of at least one other of the first group connecting lines at the first boundary and the second boundary are not aligned with each other in the second direction.

5. The display panel of claim 4, wherein a first distance between the plurality of first group connecting lines and the plurality of second group connecting lines at the first boundary is less than a second distance between the plurality of first group connecting lines and the plurality of second group connecting lines at the second boundary.

6. The display panel of claim 2, wherein the plurality of clock lines, the stage, and the plurality of pixels are sequentially arranged in the second direction, and
wherein each of the plurality of clock lines extends in the first direction, and each of the plurality of clock lines is spaced apart from one another in the second direction.

7. The display panel of claim 6, wherein the plurality of clock lines include a plurality of first group clock lines electrically connected to the plurality of first group connecting lines and a plurality of second group clock lines electrically connected to the plurality of second group connecting lines, and
wherein the plurality of first group clock lines and the plurality of second group clock lines alternate with one another in the second direction.

8. The display panel of claim 6, wherein the plurality of clock lines include a first clock line, a second clock line, a third clock line, a fourth clock line, a fifth clock line, and a sixth clock line,
wherein the plurality of transistors include a first transistor, a second transistor, a third transistor, a fourth transistor, a fifth transistor, and a sixth transistor, and each of the first to the sixth transistors is electrically connected to the first to sixth clock lines respectively, and
wherein the plurality of pixels include a first pixel, a second pixel, a third pixel, a fourth pixel, a fifth pixel, and a sixth pixel, and each of the first to sixth pixels is sequentially arranged in the first direction and connected to the first to sixth transistors in a one-to-one manner.

9. The display panel of claim 8, wherein the first transistor and the second transistor are spaced apart from each other with respect to the virtual reference line, the third transistor and the fourth transistor are spaced apart from each other with respect to the virtual reference line, and the fifth transistor and the sixth transistor are spaced apart from each other with respect to the virtual reference line.

10. The display panel of claim 9, wherein the first transistor is disposed closer to the plurality of clock lines than the fifth transistor, and the third transistor is disposed between the first transistor and the fifth transistor, and
wherein the second transistor is disposed closer to the plurality of clock lines than the sixth transistor, and the fourth transistor is disposed between the second transistor and the sixth transistor.

11. The display panel of claim 10, wherein a gap between the first transistor and the second transistor is less than a gap between the fifth transistor and the sixth transistor.

12. The display panel of claim 9, further comprising:
a voltage line disposed between the stage and the plurality of pixels; and
a plurality of intermediate connecting lines including a first intermediate connecting line, a second intermediate connecting line, a third intermediate connecting line, a fourth intermediate connecting line, a fifth intermediate connecting line, and a sixth intermediate connecting line, each of the plurality of intermediate connecting lines being connected to the first to sixth transistors in a one-to-one manner,
wherein the first to sixth intermediate connecting lines are sequentially arranged in the first direction in an area where the voltage line is disposed.

13. The display panel of claim 9, wherein the fifth transistor is disposed closer to the plurality of clock lines than the first transistor, and the third transistor is disposed between the first transistor and the fifth transistor, and
wherein the sixth transistor is disposed closer to the plurality of clock lines than the second transistor, and the fourth transistor is disposed between the second transistor and the sixth transistor.

14. The display panel of claim 13, wherein a gap between the first transistor and the second transistor is greater than a gap between the fifth transistor and the sixth transistor.

15. The display panel of claim 1, wherein, in a first mode in which the display panel operates at a first frequency, a plurality of clock signals transferred to the plurality of clock lines have different phases from one another, and
Wherein, in a second mode in which the display panel operates at a second frequency higher than the first frequency, at least two clock signals among the plurality of clock signals have the same phase.

16. An electronic device comprising:
a display panel in which a display area and a non-display area adjacent to the display area are defined,
wherein the display panel includes:
a plurality of pixels disposed in the display area; and
a stage disposed in the non-display area and outputting a plurality of scan signals to the plurality of pixels,
wherein the plurality of pixels include a first pixel, a second pixel, a third pixel, a fourth pixel, a fifth pixel, and a sixth pixel, which are sequentially arranged in a first direction,
wherein the stage includes a first transistor, a second transistor, a third transistor, a fourth transistor, a fifth transistor, and a sixth transistor, which are connected to the first to sixth pixels in a one-to-one manner and output the plurality of scan signals,
wherein the first transistor and the second transistor face each other in the first direction, the third transistor and the fourth transistor face each other in the first direction, and the fifth transistor and the sixth transistor face each other in the first direction, and
wherein the third transistor is disposed between the first transistor and the fifth transistor, and the fourth transistor is disposed between the second transistor and the sixth transistor.

17. The electronic device of claim 16, wherein the display panel further includes:
a plurality of clock lines disposed in the non-display area and providing a plurality of clock signals to the stage; and
a plurality of connecting lines disposed in the non-display area and including a first connecting line, a second connecting line, a third connecting line, a fourth connecting line, a fifth connecting line, and a sixth connecting line, the first to sixth connecting lines connected to the first to sixth transistors in a one-to-one manner and transferring the plurality of clock signals, and
wherein the first connecting line, the third connecting line, and the fifth connecting line are spaced apart from the second connecting line, the fourth connecting line, and the sixth connecting line with respect to a virtual reference line extending in a second direction.

18. The electronic device of claim 17, wherein a first area in which the plurality of clock lines are disposed, a second area in which the stage is disposed, and a third area between the first area and the second area are defined in the display panel,
wherein the third area includes a first boundary adjacent to the first area and extending in the first direction, and a second boundary adjacent to the second area and extending in the first direction, and
wherein the first to sixth connecting lines have a bent shape in the third area.

19. The electronic device of claim 18, wherein a first distance between the first connecting line and the second connecting line at the first boundary is less than a second distance between the first connecting line and the second connecting line at the second boundary.

20. The electronic device of claim 18, wherein a first distance between the fifth connecting line and the sixth connecting line at the first boundary is less than a second distance between the fifth connecting line and the sixth connecting line at the second boundary.
